(19) United States
(12) Patent Application Publication
(10) Pub. No.: US 2025/0197558 A1
(43) Pub. Date: Jun. 19, 2025

(54) PROTECTIVE-FILM FORMING COMPOSITION

(71) Applicant: NISSAN CHEMICAL CORPORATION, Tokyo (JP)

(72) Inventor: Satoshi KAMIBAYASHI, Toyama-shi (JP)

(73) Assignee: NISSAN CHEMICAL CORPORATION, Tokyo (JP)

(21) Appl. No.: 18/849,003

(22) PCT Filed: Mar. 9, 2023
(86) PCT No.: PCT/JP2023/009020

§ 371 Date: Sep. 20, 2024

(30) Foreign Application Priority Data
Mar. 24, 2022 (JP) 2022-048638

(51) Int. Cl. C08G 59/26; C08G 59/24; C08G 59/42; H01L 21/027; H01L 21/311

(52) U.S. Cl. CPC C08G 59/26; C08G 59/245; C08G 59/4207; H01L 21/0275; H01L 21/31111; H01L 21/31138; H01L 21/31144

(57) ABSTRACT

A polymer having a partial structure represented by the following formula (1), a partial structure represented by the following formula (2), and a partial structure represented by the following formula (3):

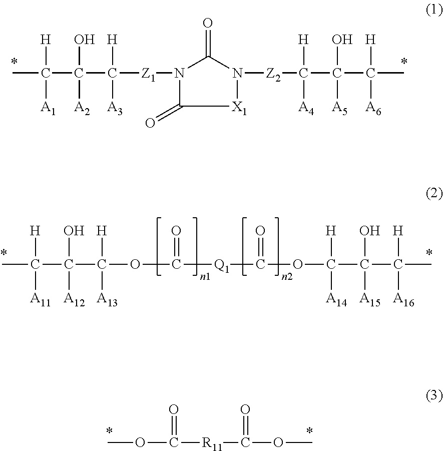

wherein in the formula (2), Q₁ represents a divalent organic group having an aromatic hydrocarbon ring or an aliphatic hydrocarbon ring, and in the formula (3), R₁₁ represents an alkylene group having 1 to 10 carbon atoms.

### TECHNICAL FIELD

The present invention relates to a composition for forming a protective film excellent in resistance particularly to a wet etching solution for a semiconductor in a lithography process in semiconductor manufacturing. The present invention also relates to a polymer that can be suitably used in the protective-film forming composition. The present invention also relates to a protective film formed from the composition, a method for manufacturing a substrate with a resist pattern to which the protective film is applied, and a method for manufacturing a semiconductor device.

### BACKGROUND ART

In semiconductor manufacturing, a lithography process for forming a resist pattern having a desired shape by providing a resist underlayer film between a substrate and a resist film formed thereon is widely known. The substrate is processed after the resist pattern is formed, and dry etching is mainly used as the step, but wet etching may be used depending on the substrate type. Patent Literature 1 discloses a resist underlayer film material having resistance to alkaline hydrogen peroxide water.

### CITATION LIST

### Patent Literature

Patent Literature 1: JP 2018-173520 A

### SUMMARY OF INVENTION

### Technical Problem

When a protective film for a semiconductor substrate is formed using a protective-film forming composition, and a base substrate is processed by wet etching using the protective film as an etching mask, the protective film is required to have a good mask function (That is, the masked part can protect the substrate.) with respect to a wet etching solution for a semiconductor and resistance to a solvent (solvent resistance) contained in a resist composition. In addition, in a manufacturing step of the semiconductor device, when the amount of the sublimate generated from the protective film is large, problems such as contamination of the top plate and the inside of the pipe of the baker used at the time of firing occur. In addition, it is required to embed a resin without a void (air space) in a fine structure on a semiconductor substrate which is being miniaturized.

The present invention has been made in view of the above circumstances, and an object of the present invention is to provide a protective-film forming composition in which a resin can be embedded without voids (air spaces) in a microstructure, the composition being capable of forming a protective film excellent in resistance to a wet etching solution for a semiconductor and excellent in resistance to a solvent contained in a resist composition while suppressing the generation amount of a sublimate. Another object of the present invention is to provide a polymer that can be suitably used in the protective-film forming composition. Another object of the present invention is to provide a protective film formed from the protective-film forming composition, a method for manufacturing a substrate with a resist pattern to which the protective film is applied, and a method for manufacturing a semiconductor device.

### Solution to Problem

As a result of intensive studies to solve the above-described problems, the present inventors have found that the above-described problems can be solved by including a specific polymer in a protective-film forming composition, and have completed the present invention.

That is, the present invention includes the following aspects.

[1] A polymer having a partial structure represented by the following formula (1), a partial structure represented by the following formula (2), and a partial structure represented by the following formula (3):

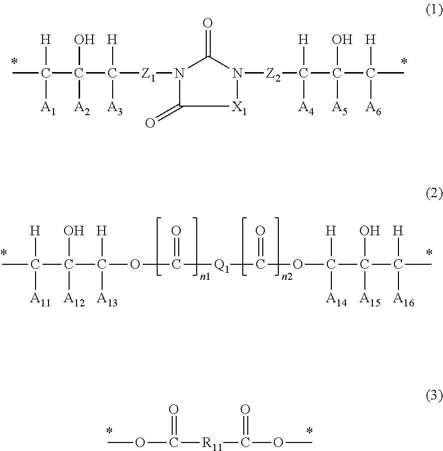

wherein in the formula (1), X₁ represents a divalent group represented by the following formula (1-1), the following formula (1-2), or the following formula (1-3); Z₁ and Z₂ each independently represent a direct bond or a divalent group represented by the following formula (1-4); A₁, A₂, A₃, A₄, A₅, and A₆ each independently represent a hydrogen atom, a methyl group or an ethyl group; and * represents a bond;
in the formula (2), Q₁ represents a divalent organic group having an aromatic hydrocarbon ring or an aliphatic hydrocarbon ring; A₁₁, A₁₂, A₁₃, A₁₄, A₁₅, and A₁₆ each independently represent a hydrogen atom, a methyl group, or an ethyl group; n1 and n2 each independently represent 0 or 1; and * represents a bond;
in the formula (3), R₁ represents an alkylene group having 1 to 10 carbon atoms; and * represents a bond;

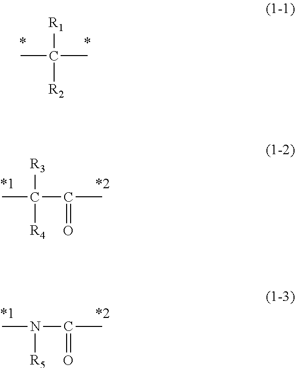

in the formulae (1-1) to (1-3), R₁ to R₅ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group or a phenyl group, and the phenyl group may be substituted by at least one monovalent group selected from the group consisting of an alkyl group having 1 to 6 carbon atoms, a halogen atom, an alkoxy group having 1 to 6 carbon atoms, a nitro group, a cyano group and an alkylthio group having 1 to 6 carbon atoms; R₁ and R₂ may be bonded to each other to form a ring having 3 to 6 carbon atoms; R₃ and R₄ may be bonded to each other to form a ring having 3 to 6 carbon atoms; * represents a bond; * 1 represents a bond bonded to a carbon atom; and *2 represents a bond bonded to a nitrogen atom; and

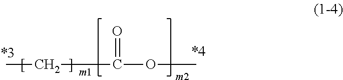

in the formula (1-4), m1 is an integer of 1 to 4; m2 is 0 or 1; * 3 represents a bond bonded to a nitrogen atom; and *4 represents a bond bonded to a carbon atom.

[2] The polymer according to [1], wherein Q₁ in the formula (2) is represented by any one of the following formulas (2-1) to (2-4):

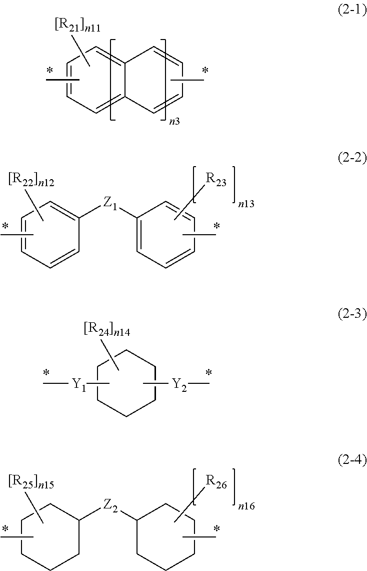

wherein in the formulas (2-1) to (2-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms; and * represents a bond;
in the formula (2-1), n3 represents 0 or 1; when n3 is 0, n11 represents an integer of 0 to 4; when n3 is 1, n11 represents an integer of 0 to 6; and when R₂₁ is 2 or more, 2 or more R₂₁ may be the same or different;
in the formula (2-2), Z₁ represents a single bond, an oxygen atom, a sulfur atom, a carbonyl group, a sulfonyl group, or an alkylene group having 1 to 6 carbon atoms; n12 and n13 each independently represent an integer of 0 to 4; when R₂₂ is 2 or more, 2 or more R₂₂ may be the same or different; and when R₂₃ is 2 or more, 2 or more R₂₃ may be the same or different;
in the formula (2-3), Y1 and Y2 each independently represent a single bond or an alkylene group having 1 to 6 carbon atoms; n14 represents an integer of 0 to 4; and when R₂₄ is 2 or more, 2 or more R₂₄ may be the same or different; and
in the formula (2-4), Z₂ represents a single bond, an oxygen atom, a sulfur atom, a carbonyl group, a sulfonyl group, or an alkylene group having 1 to 6 carbon atoms; n15 and n16 each independently represent an integer of 0 to 4; when R₂₅ is 2 or more, 2 or more R₂₅ may be the same or different; and when R₂₆ is 2 or more, 2 or more R₂₆ may be the same or different.

[3] The polymer according to [1] or [2], wherein X₁ in the formula (1) is represented by the formula (1-3).

[4] The polymer according to any one of [1] to [3], wherein a molar ratio (M1:M2) between the partial structure (M1) represented by the formula (1) and the partial structure (M2) represented by the formula (2) is 95:5 to 40:60.

[5] The polymer according to any one of [1] to [4], wherein a molar ratio [(M1+M2):M3] of a sum of the partial structure (M1) represented by the formula (1) and the partial structure (M2) represented by the formula (2) to the partial structure represented by the formula (3) is 60:40 to 40:60.

[6] The polymer according to any one of [1] to [5], having a repeating unit represented by the following formula (A) and a repeating unit represented by the following formula (B):

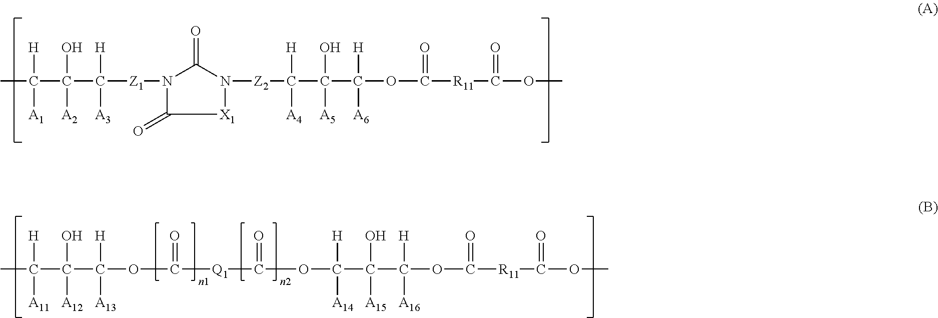

wherein in the formula (A), X₁, Z₁, Z₂, A₁, A₂, A₃, A₄, A₅, and A₆ are the same as X₁, Z₁, Z₂, A₁, A₂, A₃, A₄, A₅, and A₆ in the formula (1), respectively, R₁₁ is the same as R₁₁ in the formula (3),
in the formula (B), Q₁, A₁₁, A₁₂, A₁₃, A₁₄, A₁₅, A₁₆, n1 and n2 are the same as Q₁, A₁₁, A₁₂, A₁₃, A₁₄, A₁₅, A₁₆, n1 and n2 in the formula (2), respectively, R₁₁ is the same as R₁₁ in the formula (3).

[7] The polymer according to any one of [1] to [6], having a weight average molecular weight of 1,000 to 50,000.

[8] A protective-film forming composition for forming a protective film for protecting an inorganic film formed on a surface of a semiconductor substrate from wet etching, the composition including:
the polymer according to any one of [1] to [7] and a solvent.

[9] The protective-film forming composition according to [8], including at least one of a crosslinking agent, an acid generator, a compound represented by the following formula (1a), and a compound represented by formula (1b):

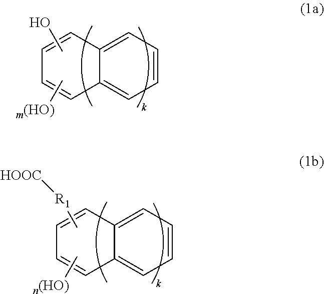

wherein in the formulae (1a) and (1b), R₁ represents a single bond, an alkylene group having 1 to 4 carbon atoms, or an alkenylene group having 2 to 4 carbon atoms having one or two carbon-carbon double bonds; k represents 0 or 1; m represents an integer of 1 to 3; and n represents an integer of 2 to 4.

[10] A protective film for a wet etching solution for a semiconductor which is a baked product of an applied film formed of the protective-film forming composition according to [8] or [9].

[11] A method for manufacturing a substrate with a protective film, the method including a step of forming a protective film by applying the protective-film forming composition according to [8] or [9] on a stepped semiconductor substrate and baking the composition.

[12] A method for manufacturing a substrate with a resist pattern used for manufacturing a semiconductor, the method including:
a step of applying the protective-film forming composition according to claim [8] or [9] on a semiconductor substrate and baking the composition to form a protective film as a resist underlayer film; and
a step of forming a resist film on the protective film directly or via another layer, and then forming a resist pattern by exposure and development.

[13] A method for manufacturing a semiconductor device, the method including the steps of: forming a protective film using the protective-film forming composition according to claim [8] or [9] on a semiconductor substrate having an inorganic film formed on a surface; forming a resist pattern on the protective film directly or via another layer; dry-etching the protective film using the resist pattern as a mask to expose a surface of the inorganic film; and wet-etching the inorganic film using a wet etching solution for a semiconductor using the protective film after the dry etching as a mask.

### Advantageous Effects of Invention

According to the present invention, it is possible to provide a protective-film forming composition capable of embedding a resin without voids (air spaces) in a microstructure, the composition being capable of forming a protective film excellent in resistance to a wet etching solution for a semiconductor and excellent in resistance to a solvent contained in a resist composition while suppressing the generation amount of a sublimate. Further, according to the present invention, a polymer that can be suitably used for the protective-film forming composition can be provided. Further, according to the present invention, it is possible to provide a protective film formed from the protective-film forming composition, a method for manufacturing a substrate with a resist pattern to which the protective film is applied, and a method for manufacturing a semiconductor device.

### BRIEF DESCRIPTION OF DRAWINGS

FIG. 1 is a schematic view of a cross-sectional shape of a trench.

FIG. 2 is a cross-sectional photograph (SEM photograph) of a trench in which a protective film of Example 1 is formed.

FIG. 3 is a cross-sectional photograph (SEM photograph) of a trench in which a protective film of Example 2 is formed.

FIG. 4 is a cross-sectional photograph (SEM photograph) of a trench in which a protective film of Example 4 is formed.

FIG. 5 is a cross-sectional photograph (SEM photograph) of a trench in which a protective film of Example 7 is formed.

FIG. 6 is a cross-sectional photograph (SEM photograph) of a trench in which a protective film of Example 8 is formed.

FIG. 7 is a cross-sectional photograph (SEM photograph) of a trench in which a protective film of Example 10 is formed.

FIG. 8 is a cross-sectional photograph (SEM photograph) of a trench in which a protective film of Comparative Example 1 is formed.

### DESCRIPTION OF EMBODIMENTS

### (Protective-Film Forming Composition)

The protective-film forming composition of the present invention is a composition for forming a protective film.

The protective film is a protective film that protects the inorganic film of the semiconductor substrate having the inorganic film formed on the surface from wet etching.

The protective-film forming composition contains a polymer and a solvent.

### <Polymer>

The polymer contained in the protective-film forming composition has a partial structure represented by the following formula (1), a partial structure represented by the following formula (2), and a partial structure represented by the following formula (3).

Such polymers are also the subject of the invention.

When the protective-film forming composition contains the polymer, a protective film excellent in resistance to a wet etching solution for a semiconductor and excellent in resistance to a solvent contained in the resist composition can be formed while suppressing the generation amount of a sublimate.

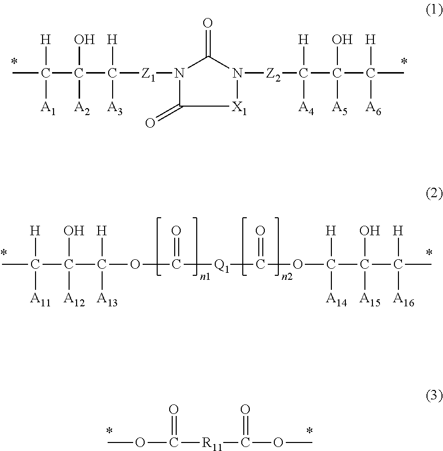

(In the formula (1), X₁ represents a divalent group represented by the following formula (1-1), the following formula (1-2), or the following formula (1-3); Z₁ and Z₂ each independently represent a direct bond or a divalent group represented by the following formula (1-4); A₁, A₂, A₃/A₄, A₅, and A₆ each independently represent a hydrogen atom, a methyl group or an ethyl group; and * represents a bond.

In the formula (2), Q₁ represents a divalent organic group having an aromatic hydrocarbon ring or an aliphatic hydrocarbon ring; A₁₁, A₁₂, A₁₃, A₁₄, A₁₅, and A₁₆ each independently represent a hydrogen atom, a methyl group, or an ethyl group; n1 and n2 each independently represent 0 or 1; and * represents a bond.

In the formula (3), R₁₁ represents an alkylene group having 1 to 10 carbon atoms; and * represents a bond.)

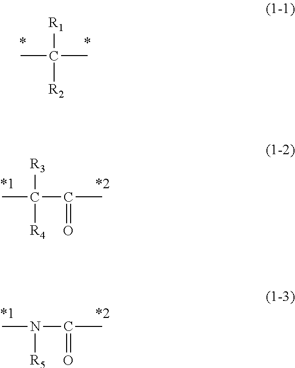

(In the formulae (1-1) to (1-3), R₁ to R₅ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group or a phenyl group, and the phenyl group may be substituted by at least one monovalent group selected from the group consisting of an alkyl group having 1 to 6 carbon atoms, a halogen atom, an alkoxy group having 1 to 6 carbon atoms, a nitro group, a cyano group and an alkylthio group having 1 to 6 carbon atoms; R₁ and R₂ may be bonded to each other to form a ring having 3 to 6 carbon atoms; R₃ and R₄ may be bonded to each other to form a ring having 3 to 6 carbon atoms; * represents a bond; * 1 represents a bond bonded to a carbon atom; and *2 represents a bond bonded to a nitrogen atom.)

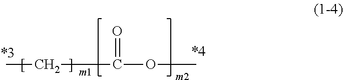

(In the formula (1-4), m1 is an integer of 1 to 4; m2 is 0 or 1; * 3 represents a bond bonded to a nitrogen atom; and *4 represents a bond bonded to a carbon atom.)

Examples of the alkyl group having 1 to 10 carbon atoms which may be interrupted by an oxygen atom or a sulfur atom in R₁ to R₅ in the formulae (1-1) to (1-3) include an alkyl group having 1 to 10 carbon atoms, an alkoxy group having 1 to 10 carbon atoms, an alkoxyalkyl group having 2 to 10 carbon atoms, an alkoxyalkoxyalkyl group having 3 to 10 carbon atoms, an alkylthio group having 1 to 10 carbon atoms, and an alkylthioalkyl group having 2 to 10 carbon atoms.

The alkyl group having 1 to 10 carbon atoms which may be interrupted by an oxygen atom or a sulfur atom may contain two or more oxygen atoms or sulfur atoms.

### <<X_{1>>}

X₁ in the formula (1) is preferably represented by formula (1-3) from the viewpoint of suitably obtaining the effect of the present invention.

Examples of the structure represented by the following (1A) in the formula (1) include:

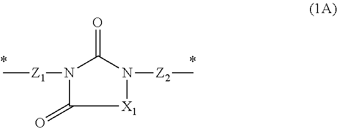

(In the formula (1A), Z₁, Z₂ and X₁ are the same as Z₁, Z₂ and X₁ in the formula (1), respectively; and * represents a bond.) Examples thereof include structures exemplified below.

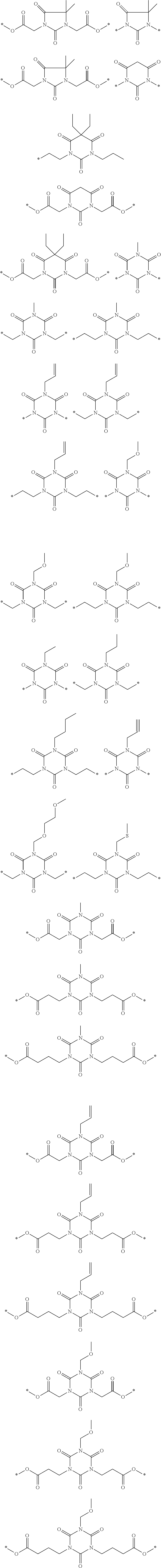

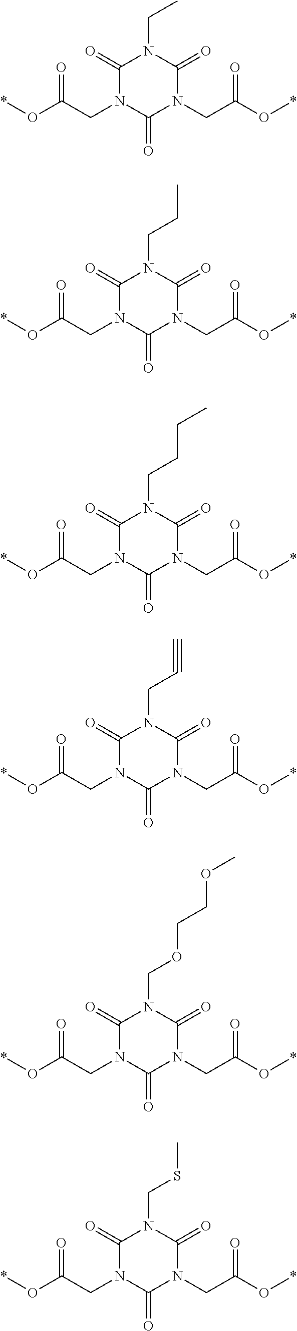

In the above structure, * represents a bond.

### <<Q_{1>>}

Q₁ in the formula (2) is preferably represented by any one of the following formulas (2-1) to (2-4) from the viewpoint of suitably obtaining the effect of the present invention.

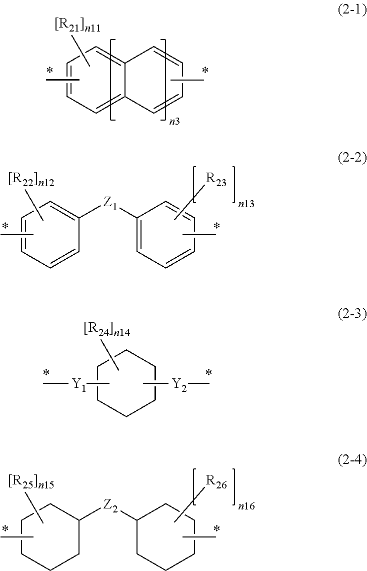

(In the formulas (2-1) to (2-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms; and * represents a bond.

In the formula (2-1), n3 represents 0 or 1; when n3 is 0, n11 represents an integer of 0 to 4; when n3 is 1, n11 represents an integer of 0 to 6; and when R₂₁ is 2 or more, 2 or more R₂₁ may be the same or different.

In the formula (2-2), Z₁ represents a single bond, an oxygen atom, a sulfur atom, a carbonyl group, a sulfonyl group, or an alkylene group having 1 to 6 carbon atoms; n12 and n13 each independently represent an integer of 0 to 4; when R₂₂ is 2 or more, 2 or more R₂₂ may be the same or different; and when R₂₃ is 2 or more, 2 or more R₂₃ may be the same or different.

In the formula (2-3), Y1 and Y2 each independently represent a single bond or an alkylene group having 1 to 6 carbon atoms; n14 represents an integer of 0 to 4; and when R₂₄ is 2 or more, 2 or more R₂₄ may be the same or different. In the formula (2-4), Z₂ represents a single bond, an oxygen atom, a sulfur atom, a carbonyl group, a sulfonyl group, or an alkylene group having 1 to 6 carbon atoms; n15 and n16 each independently represent an integer of 0 to 4; when R₂₅ is 2 or more, 2 or more R₂₅ may be the same or different; and when R₂₆ is 2 or more, 2 or more R₂₆ may be the same or different.

In the present specification, examples of the halogen atom include a fluorine atom, a chlorine atom, a bromine atom, and an iodine atom.

In the present specification, the alkyl group is not limited to a linear form, and may be a branched form or a cyclic form. Examples of the linear or branched alkyl group include a methyl group, an ethyl group, an isopropyl group, a tert-butyl group, and a n-hexyl group. Examples of the cyclic alkyl group (cycloalkyl group) include a cyclobutyl group, a cyclopentyl group, and a cyclohexyl group.

In the present specification, examples of the alkoxy group include a methoxy group, an ethoxy group, an n-pentyloxy group, and an isopropoxy group.

In the present specification, examples of the alkylthio group include a methylthio group, an ethylthio group, an n-pentylthio group, and an isopropylthio group.

In the present specification, examples of the alkenyl group include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, and the like.

In the present specification, examples of the alkynyl group include a group in which a double bond of an alkenyl group listed above in “Alkenyl group” is replaced with a triple bond.

In the present specification, examples of the alkenyloxy group include a vinyloxy group, a 1-propenyloxy group, a 2-n-propenyloxy group (allyloxy group), a 1-n-butenyloxy group, and a prenyloxy group.

In the present specification, examples of the alkynyloxy group include a 2-propynyloxy group, a 1-methyl-2-propynyloxy group, a 2-methyl-2-propynyloxy group, a 2-butynyloxy group, and a 3-butynyloxy group.

In the present specification, examples of the acyl group include an acetyl group and a propionyl group.

In the present specification, examples of the aryloxy group include a phenoxy group and naphthyloxy.

In the present specification, examples of the arylcarbonyl group include a phenylcarbonyl group.

In the present specification, examples of the aralkyl group include a benzyl group and a phenethyl group.

In the present specification, examples of the alkylene group include a methylene group, an ethylene group, a 1,3-propylene group, a 2,2-propylene group, a 1-methylethylene group, a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethyloctylene group, a 1,9-nonylene group, and a 1,10-decylene group.

Examples of the structure represented by the following (2A) in the formula (2) include:

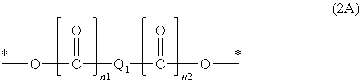

(In the formula (2A), Q₁, n1, and n2 are the same as Q₁, n1, and n2 in the formula (2), respectively. * represents a bond.) Examples thereof include structures exemplified below.

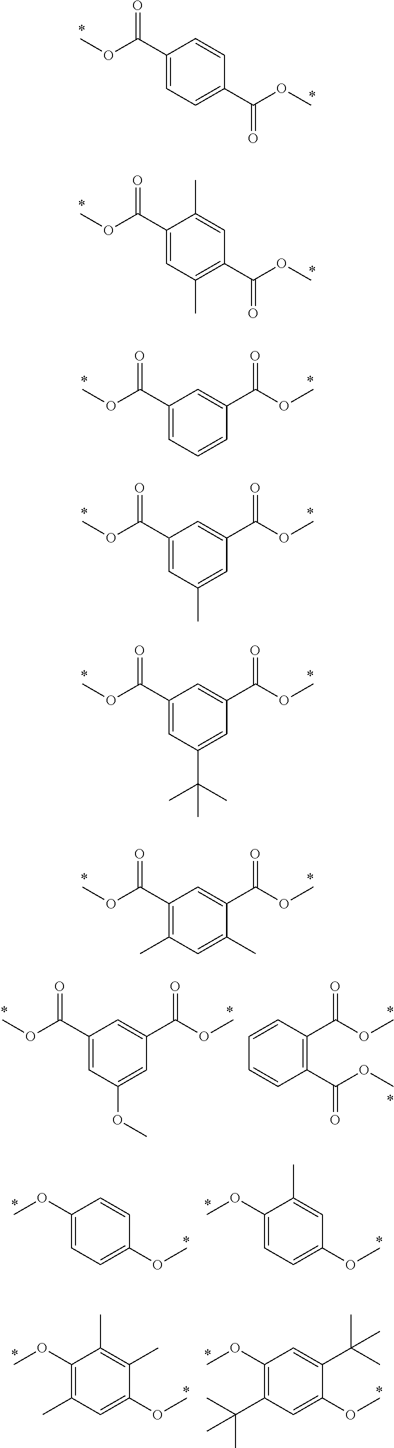

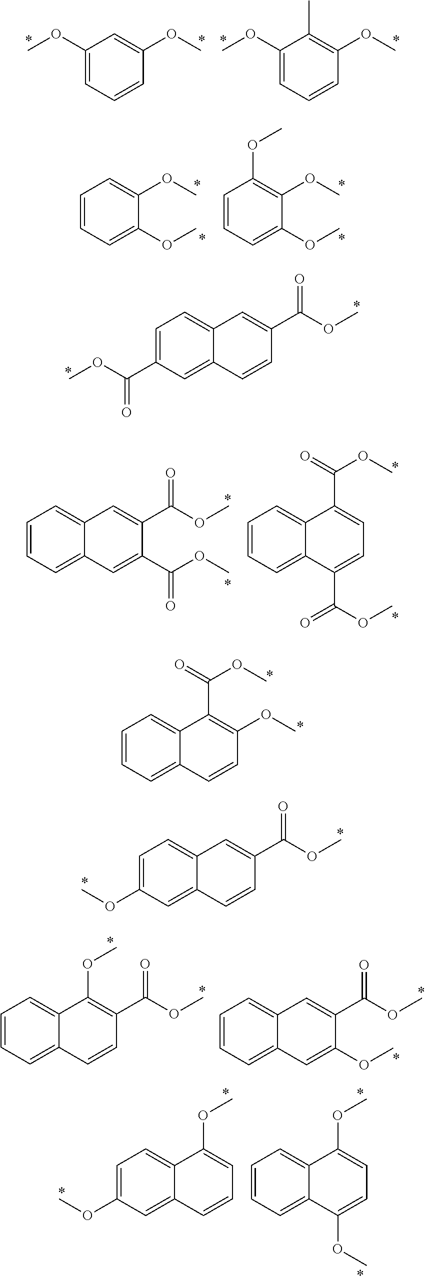

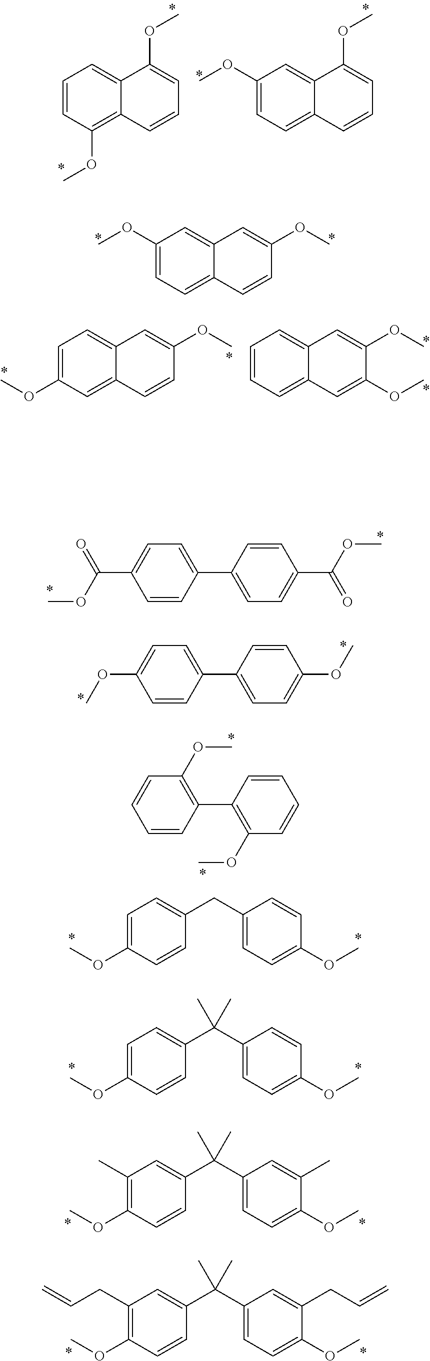

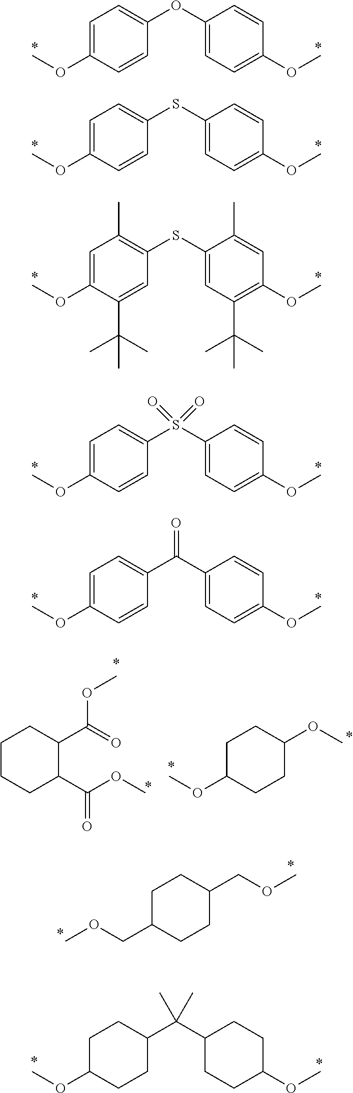

In the above structure, * represents a bond.

The alkylene group of R₁₁ in the formula (3) is, for example, an acyclic alkylene group. Examples of such an alkylene group include a linear alkylene group and a branched alkylene group.

From the viewpoint of suitably obtaining the effect of the present invention, the polymer preferably has a repeating unit represented by the formula (A) and a repeating unit represented by the following formula (B).

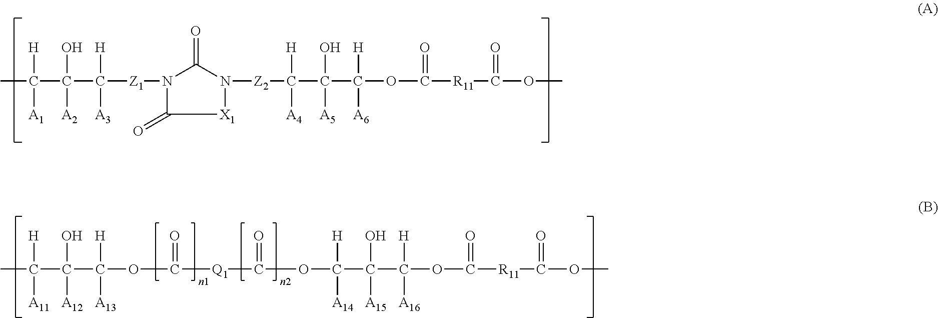

(In the formula (A), X₁, Z₁, Z₂, A₁, A₂, A₃, A₄, A₅, and A₆ are the same as X₁, Z₁, Z₂, A₁, A₂, A₃, A₄, A₅, and A₆ in the formula (1), respectively; and R₁₁ is the same as R₁₁ in the formula (3).

In the formula (B), Q₁, A₁₁, A₁₂, A₁₃, A₁₄, A₁₅, A₁₆, n1 and n2 are the same as Q₁, A₁₁, A₁₂, A₁₃, A₁₄, A₁₅, A₁₆, n1 and n2 in the formula (2), respectively; and R₁₁ is the same as R₁₁ in the formula (3).)

The molar ratio (M1:M2) between the partial structure (M1) represented by the formula (1) and the partial structure (M2) represented by the formula (2) in the polymer is not particularly limited, but is preferably 95:5 to 10:90, more preferably 95:5 to 20:80, and particularly preferably 95:5 to 40:60.

The molar ratio [(M1+M2):M3] of the sum of the partial structure (M1) represented by the formula (1) and the partial structure (M2) represented by the formula (2) to the partial structure represented by the formula (3) in the polymer is not particularly limited, but is preferably 80:20 to 20:80, more preferably 70:30 to 30:70, and particularly preferably 60:40 to 40:60.

The molar ratio (MA:MB) between the repeating unit (MA) represented by the formula (A) and the repeating unit (MB) represented by the formula (B) in the polymer is not particularly limited, but is preferably 95:5 to 10:90, more preferably 95:5 to 20:80, and particularly preferably 95:5 to 40:60.

The molar ratio of the sum of the repeating unit (MA) represented by the formula (A) and the repeating unit (MB) represented by the formula (B) to all the repeating units of the polymer is not particularly limited, but is preferably 70 mol % or more, more preferably 80 mol % or more, and particularly preferably 90 mol % or more. The upper limit is not particularly limited, but is preferably 100 mol % or less.

### <<Method for Manufacturing Polymer>>

The method for manufacturing the polymer is not particularly limited, and examples thereof include a method of reacting a diepoxy compound represented by the following formula (A1), a diepoxy compound represented by the following formula (A2), and a dicarboxylic acid represented by the following formula (A3).

For example, a diepoxy compound represented by the following formula (A1), a diepoxy compound represented by the following formula (A2), and a dicarboxylic acid represented by the following formula (A3) are dissolved in an organic solvent at an appropriate molar ratio. A polymer is obtained by polymerization in the presence of a catalyst that activates an epoxy group.

When the polymer is manufactured, a diepoxy compound other than the diepoxy compound represented by the formula (A₁) and the diepoxy compound represented by the formula (A₂) may be used in combination. When the polymer is manufactured, a dicarboxylic acid other than the dicarboxylic acid represented by the formula (A3) may be used in combination.

Examples of the catalyst for activating an epoxy group include a quaternary phosphonium salt such as tetrabutylphosphonium bromide or ethyltriphenylphosphonium bromide, and a quaternary ammonium salt such as benzyltriethylammonium chloride. As the amount of the catalyst used, an appropriate amount can be selected and used from the range of 0.1 to 10 mass % with respect to the total mass of the polymer raw material used in the reaction. As the temperature and time for the polymerization reaction, for example, optimum conditions can be selected from the range of 80 to 160° C. and 2 to 50 hours.

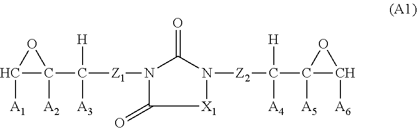

(In the formula (A1), X₁, Z₁, Z₂, A₁, A₂, A₃, A₄, A₅, and A₆ are the same as X₁, Z₁, Z₂, A₁, A₂, A₃, A₄, A₅, and A₆ in the formula (1), respectively.)

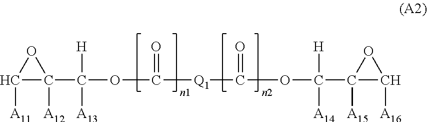

(In the formula (A2), Q₁, A₁₁, A₁₂, A₁₃, A₁₄, A₁₅, A₁₆, n1 and n2 are the same as Q₁, A₁₁, A₁₂, A₁₃, A₁₄, A₁₅, A₁₆, n1 and n2 in the formula (2), respectively.)

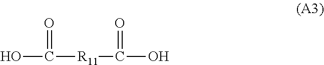

(In the formula (A3), R₁₁ is the same as R₁₁ in the formula (3).)

Examples of the diepoxy compound represented by the formula (A1) include the following diepoxy compounds.

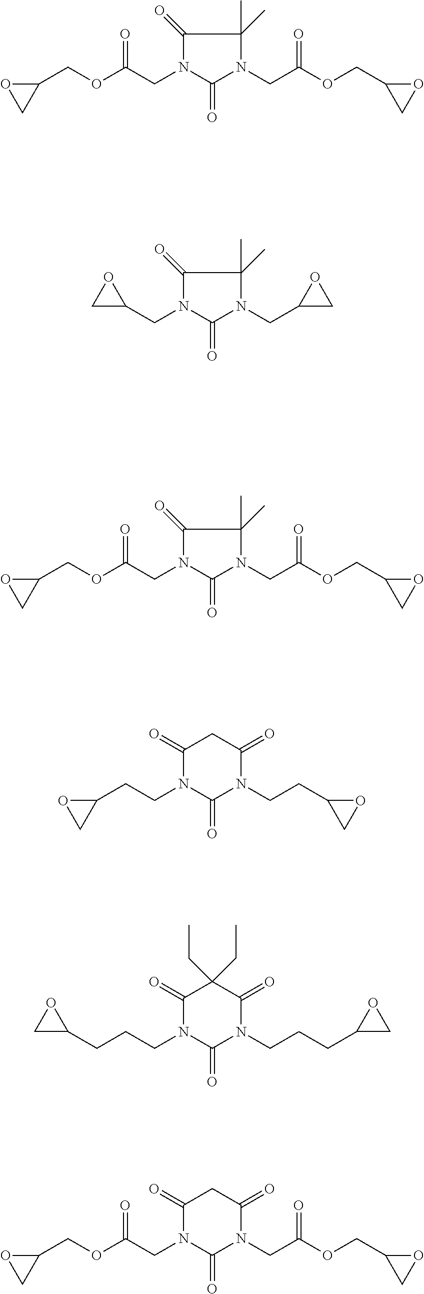

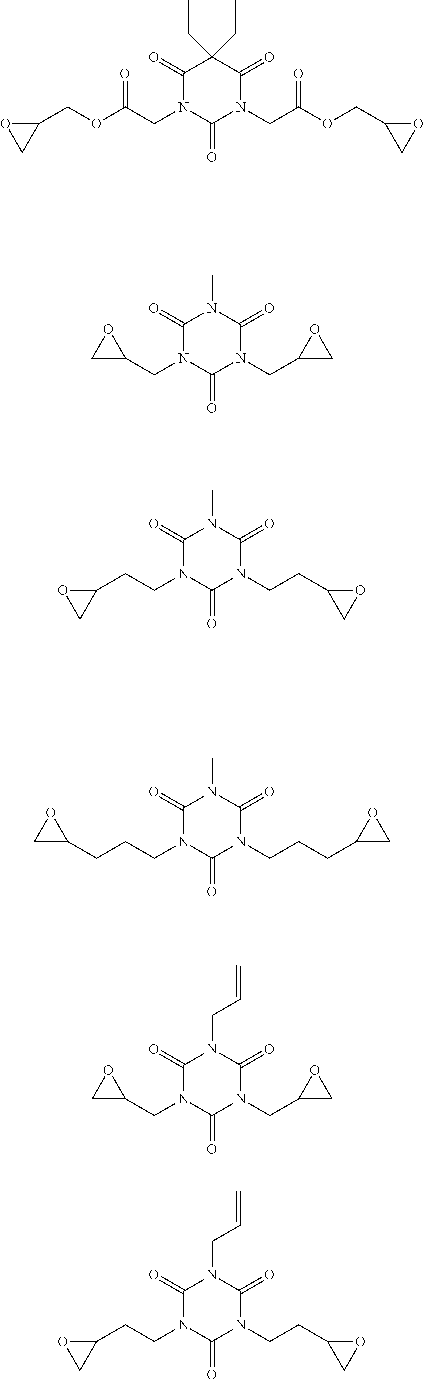

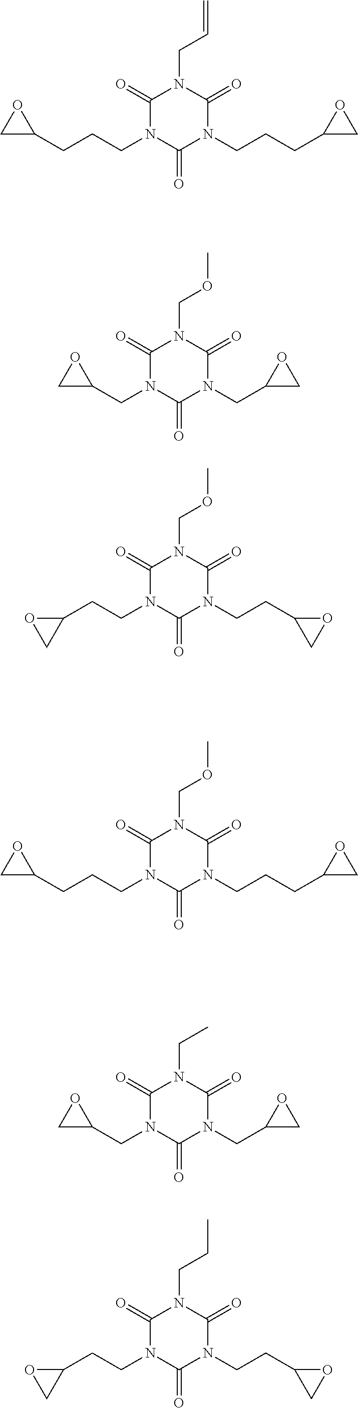

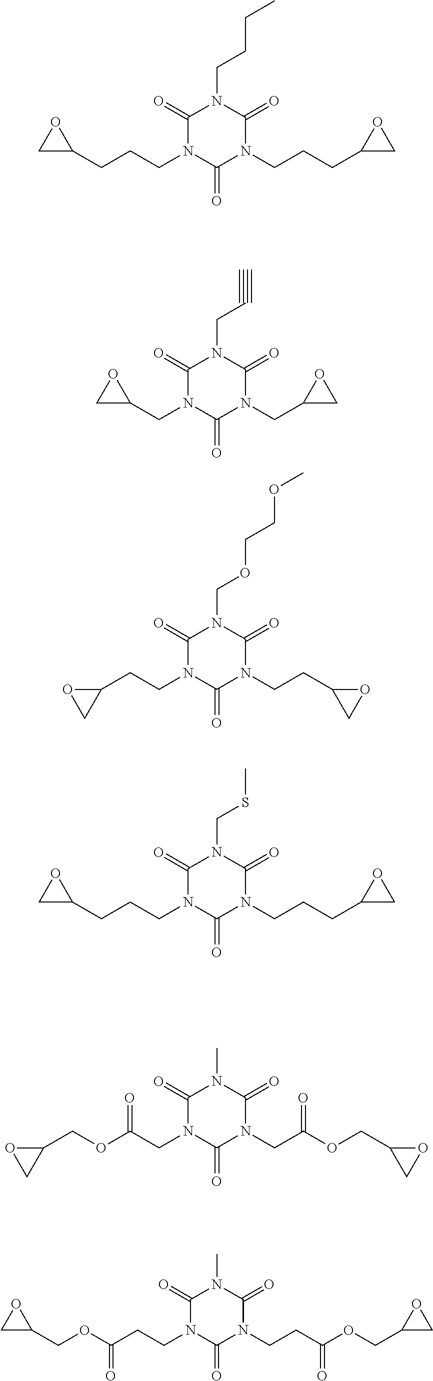

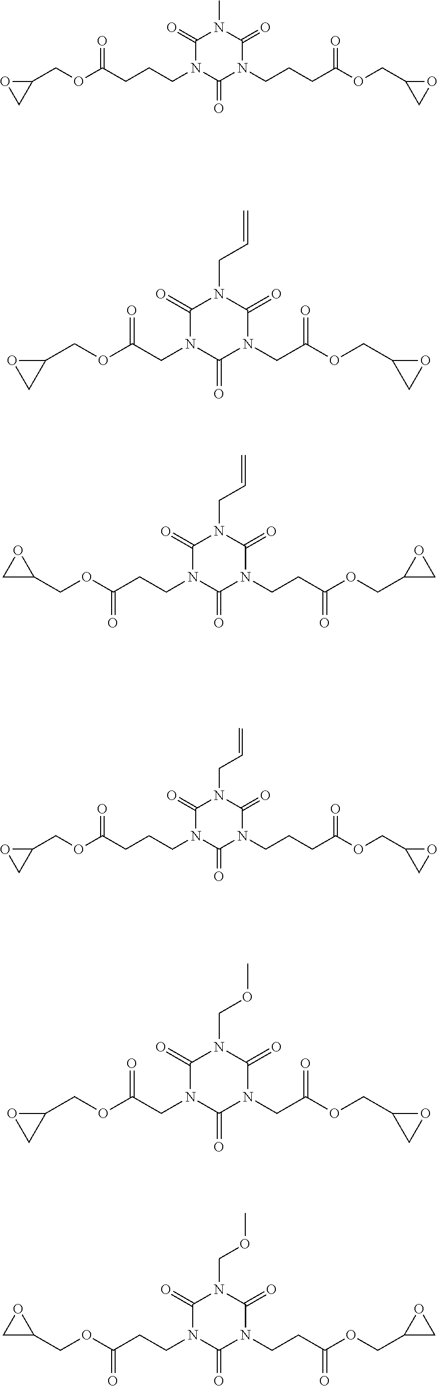

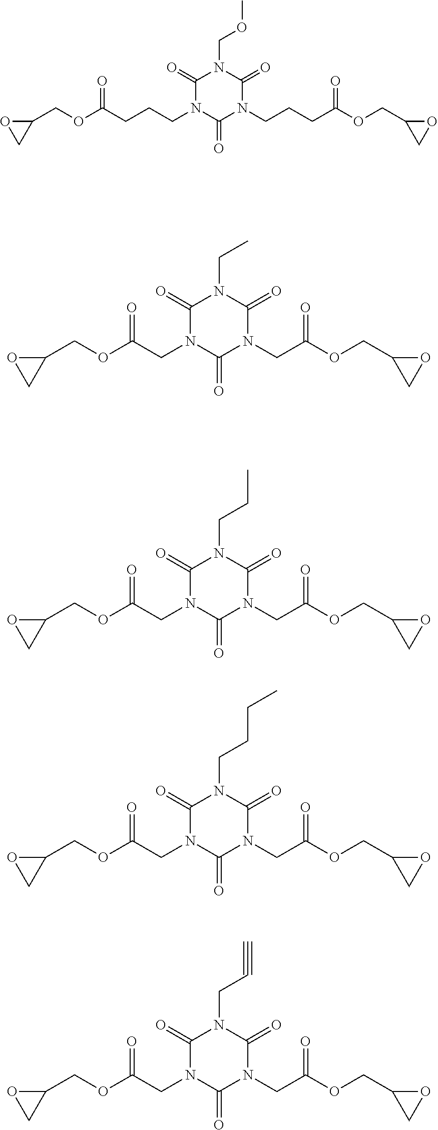

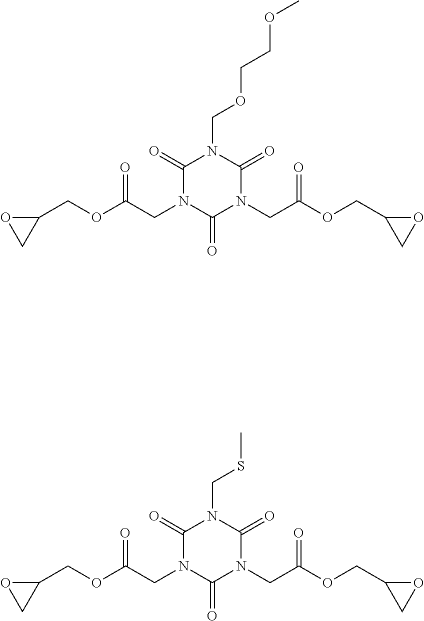

Examples of the diepoxy compound represented by the formula (A2) include the following diepoxy compounds.

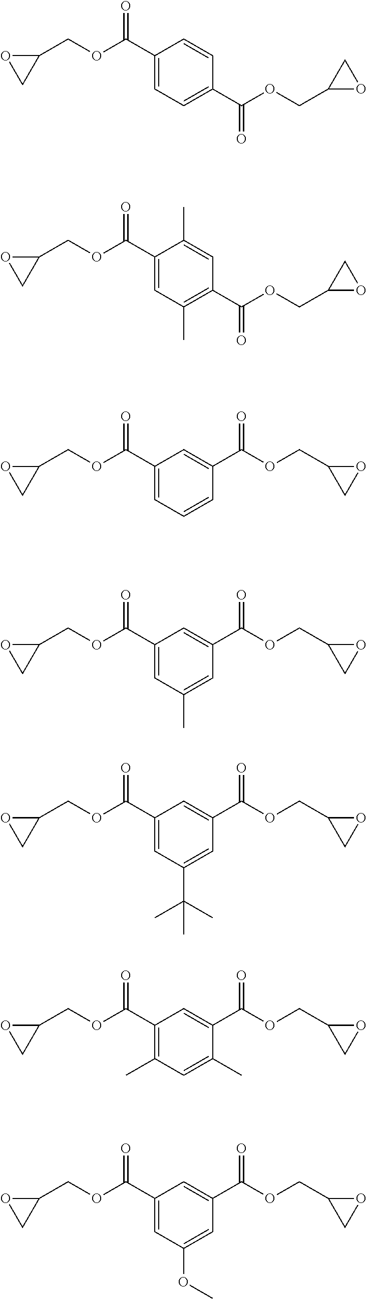

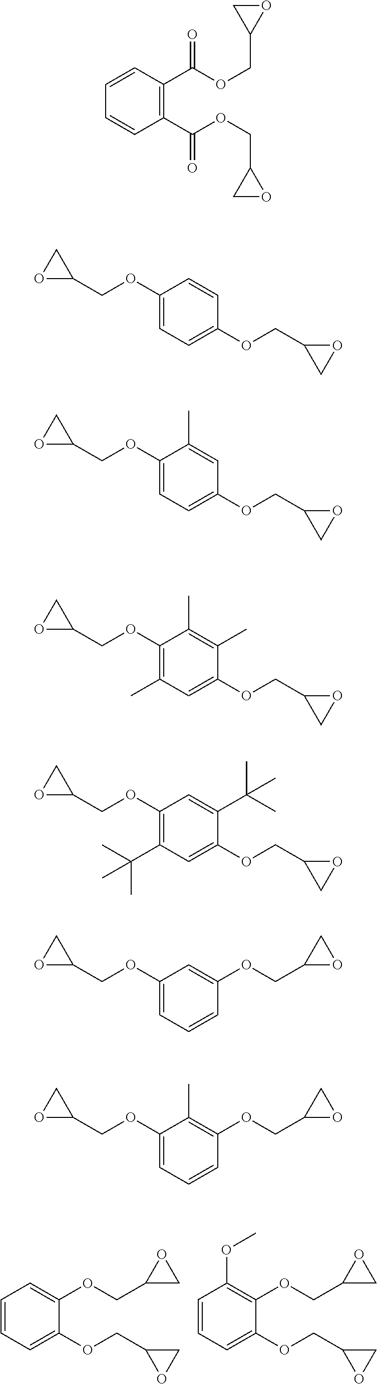

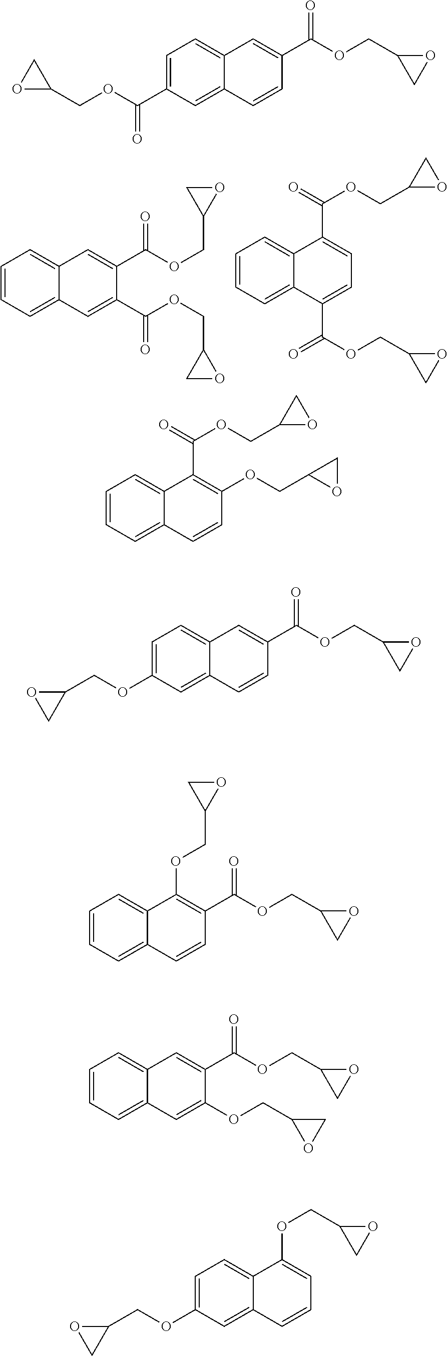

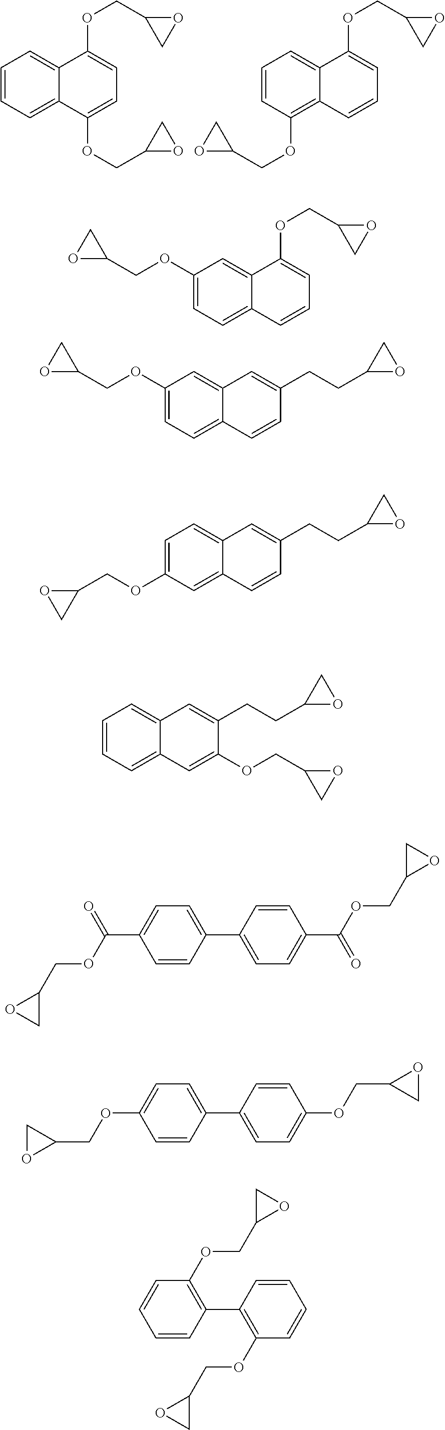

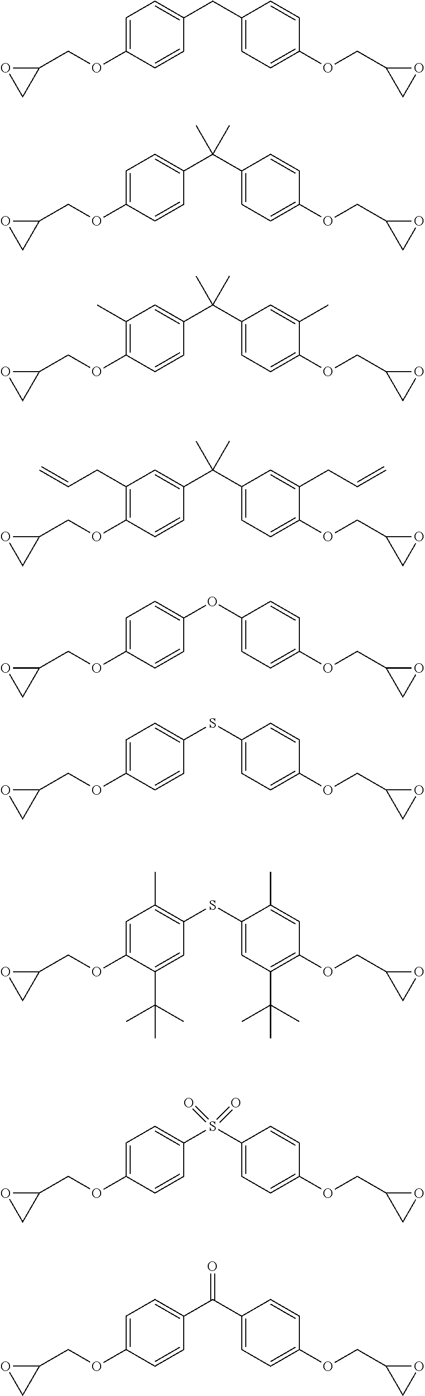

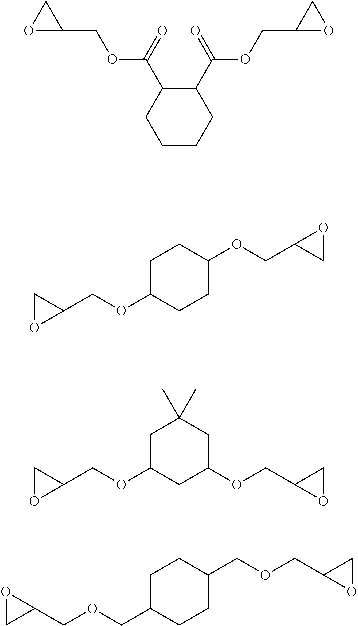 [SMILES: O=C(OCC1CO1)C1CCCCC1C(=O)OCC1CO1 ; C1CC(OCC2CO2)CCC1OCC1CO1 ; CC1(C)CC(OCC2CO2)CC(OCC2CO2)C1 ; C1CC(COCC2CO2)CCC1COCC1CO1]

Examples of the dicarboxylic acid represented by the formula (A3) include the following compounds.

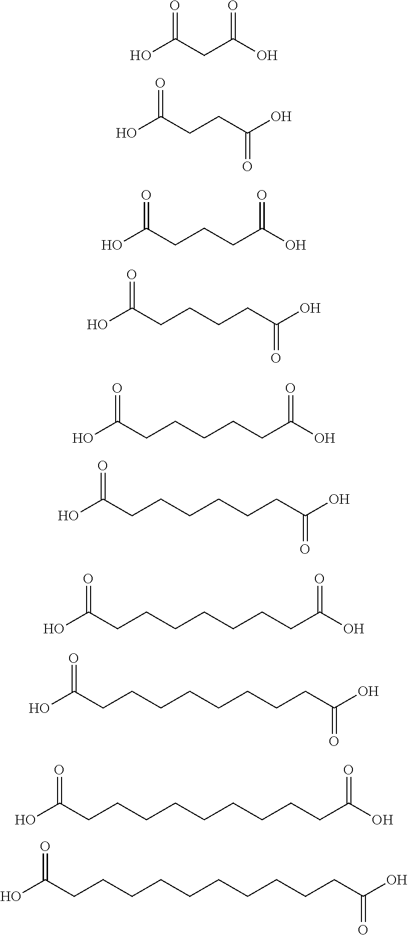

The weight average molecular weight Mw of the polymer is not particularly limited, but is preferably 1,000 to 50,000, more preferably 1,500 to 30,000, and particularly preferably 2,000 to 10,000.

In the present invention, the weight average molecular weight Mw is a value in terms of polystyrene measured by gel permeation chromatography (GPC).

### <Solvent>

The solvent used in the protective-film forming composition is not particularly limited as long as it is a solvent capable of uniformly dissolving solid contained components at normal temperature, but generally, an organic solvent used in a chemical solution for a semiconductor lithography step is preferable. Specific examples include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2 pentanol, methyl 2-hydroxyisobutyrate, ethyl 2-hydroxyisobutyrate, ethyl ethoxyacetate, ethyl acetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N, N-dimethylformamide, and N, N-dimethylacetamide. These solvents can be used alone or in combination of two or more kinds thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Crosslinking Agent>

Examples of the crosslinking agent contained as an optional component in the protective-film forming composition include melamine-based crosslinking agents having an alkoxymethyl group, substituted urea-based crosslinking agents, and polymer systems thereof.

Examples of the alkoxy group include an alkoxy group having 1 to 10 carbon atoms, and examples thereof include a methoxy group, an ethoxy group, a propoxy group, and a butoxy group. Examples of the methyl group having an alkoxy group include a methoxymethyl group, an ethoxymethyl group, a propoxymethyl group, and a butoxymethyl group. Preferably, the crosslinking agent is a crosslinking agent having at least two crosslinking forming substituents, and examples thereof include hexamethoxymethylmelamine, tetramethoxymethylbenzoguanamine, 1,3,4,6-tetrakis(methoxymethyl)glycoluril (tetramethoxymethylglycoluril) (POWDERLINK [registered trademark] 1174), 1,3,4,6-tetrakis(butoxymethyl)glycoluril, 1,3,4,6-tetrakis(hydroxymethyl)glycoluril, 1,3-bis (hydroxymethyl)urea, 1,1,3,3-tetrakis(butoxymethyl)urea, and 1,1,3,3-tetrakis(methoxymethyl)urea.

As the crosslinking agent, a crosslinking agent having high heat resistance can be used. As the crosslinking agent having high heat resistance, a compound containing a crosslinking forming substituent having an aromatic ring (for example, a benzene ring or a naphthalene ring) in the molecule can be used.

Examples of the compound include a compound having a partial structure of the following formula (H-1) and a polymer or oligomer having a repeating unit of the following formula (H-2).

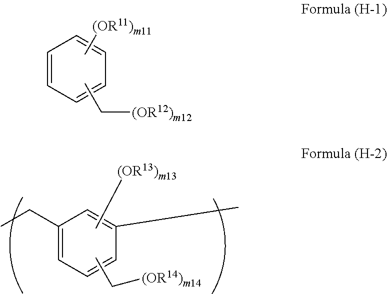

R¹¹, R¹², R¹³, and R¹⁴ each represent a hydrogen atom or an alkyl group having 1 to 10 carbon atoms, and the above-described examples can be used for these alkyl groups.

m1 satisfies 1≤m1≤(6−m2).

m2 satisfies 1≤m2≤5.

m3 satisfies 1≤m3≤(4-m2).

m4 satisfies 1≤ m4≤3.

The compounds, polymers and oligomers of the formula (H-1) and the formula (H-2) are exemplified below.

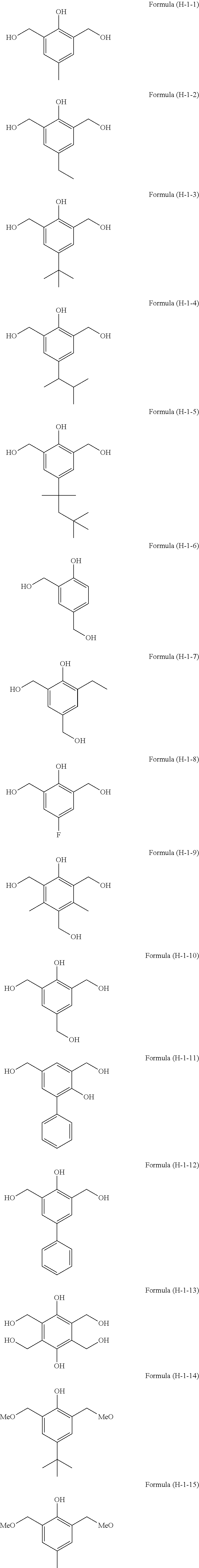

(In the formula, Me represents a methyl group.)

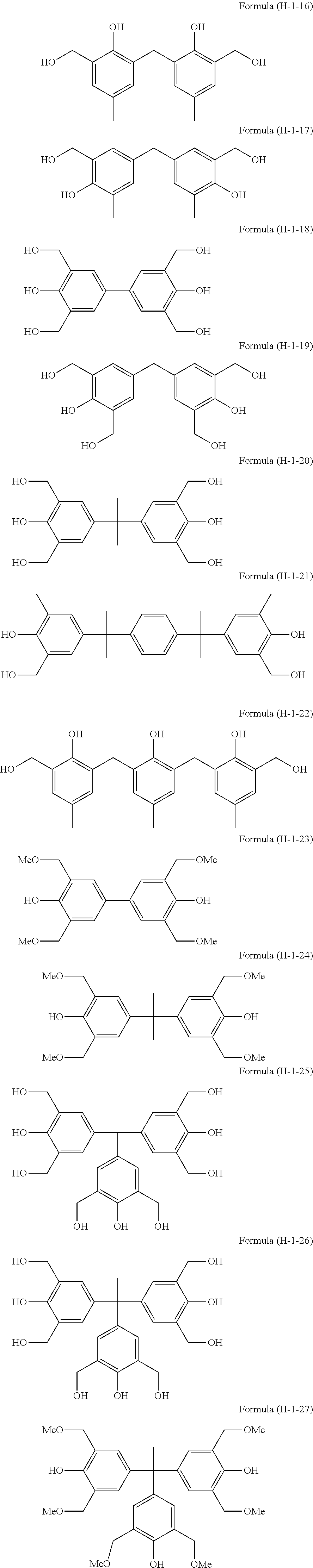

(In the formula, Me represents a methyl group.)

The compound can be obtained as a product of ASAHI YUKIZAI CORPORATION and Honshu Chemical Industry Co., Ltd. For example, a compound of formula (H-1-23) among the above crosslinking agents can be obtained as TMOM-BP (trade name) manufactured by Honshu Chemical Industry Co., Ltd. A compound of formula (H-1-20) can be obtained as trade name TM-BIP-A manufactured by ASAHI YUKIZAI CORPORATION.

In addition, the crosslinking agent may be a nitrogen-containing compound having 2 to 6 substituents represented by the following formula (1d) that bond to a nitrogen atom in one molecule, which is described in WO 2017/187969 A.

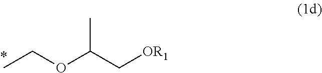

(In the formula (1d), R₁ represents a methyl group or an ethyl group. * represents a bond bonded to a nitrogen atom.)

The nitrogen-containing compound having 2 to 6 substituents represented by the formula (1d) in one molecule may be a glycoluril derivative represented by the following formula (1E).

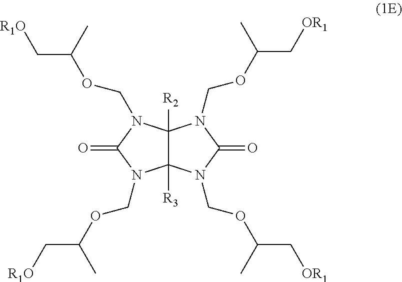

(In the formula (1E), four R₁s each independently represent a methyl group or an ethyl group, and R₂ and R₃ each independently represent a hydrogen atom, an alkyl group having 1 to 4 carbon atoms, or a phenyl group.)

Examples of the glycoluril derivative represented by the formula (1E) include compounds represented by the following formulas (1E-1) to (1E-6).

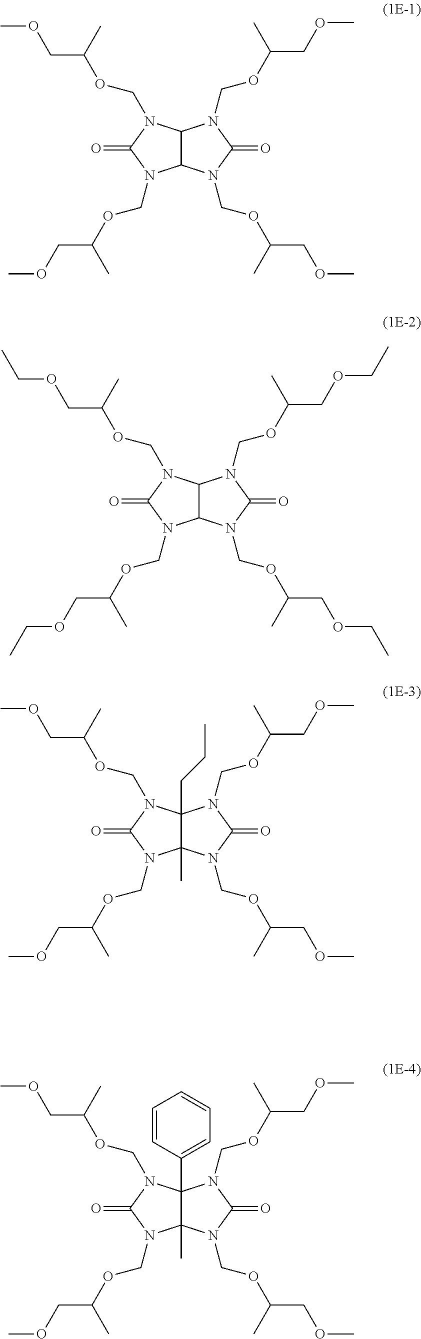

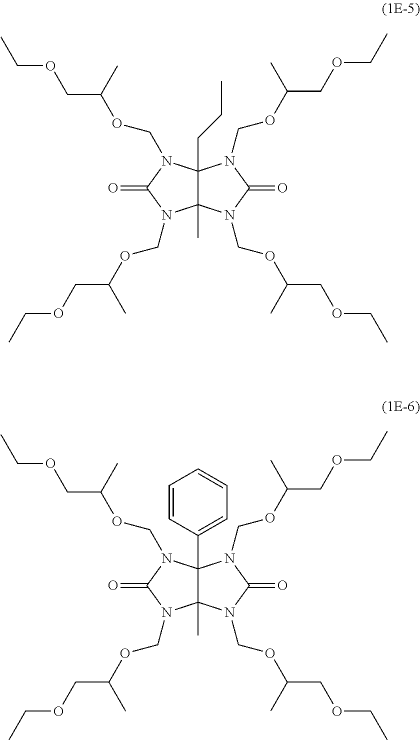

The nitrogen-containing compound having 2 to 6 substituents represented by the formula (1d) in one molecule is obtained by reacting a nitrogen-containing compound having 2 to 6 substituents represented by the following formula (2d) that bond to a nitrogen atom in one molecule with at least one compound represented by the following formula (3d).

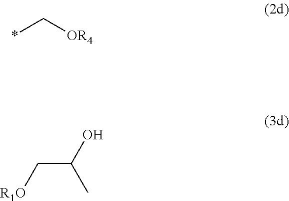

(In the formula (2d) and the formula (3d), R₁ represents a methyl group or an ethyl group, and R₄ represents an alkyl group having 1 to 4 carbon atoms. * represents a bond bonded to a nitrogen atom.)

The glycoluril derivative represented by the formula (1E) is obtained by reacting a glycoluril derivative represented by the following formula (2E) with at least one compound represented by the formula (3d).

The nitrogen-containing compound having 2 to 6 substituents represented by the formula (2d) in one molecule is, for example, a glycoluril derivative represented by the following formula (2E).

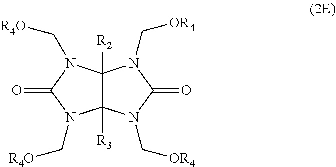

(In the formula (2E), R₂ and R₃ each independently represent a hydrogen atom, an alkyl group having 1 to 4 carbon atoms, or a phenyl group, and R₄ each independently represent an alkyl group having 1 to 4 carbon atoms.)

Examples of the glycoluril derivative represented by the formula (2E) include compounds represented by the following formulas (2E-1) to (2E-4). Furthermore, examples of the compound represented by the formula (3d) include compounds represented by the following formulas (3d-1) and (3d-2).

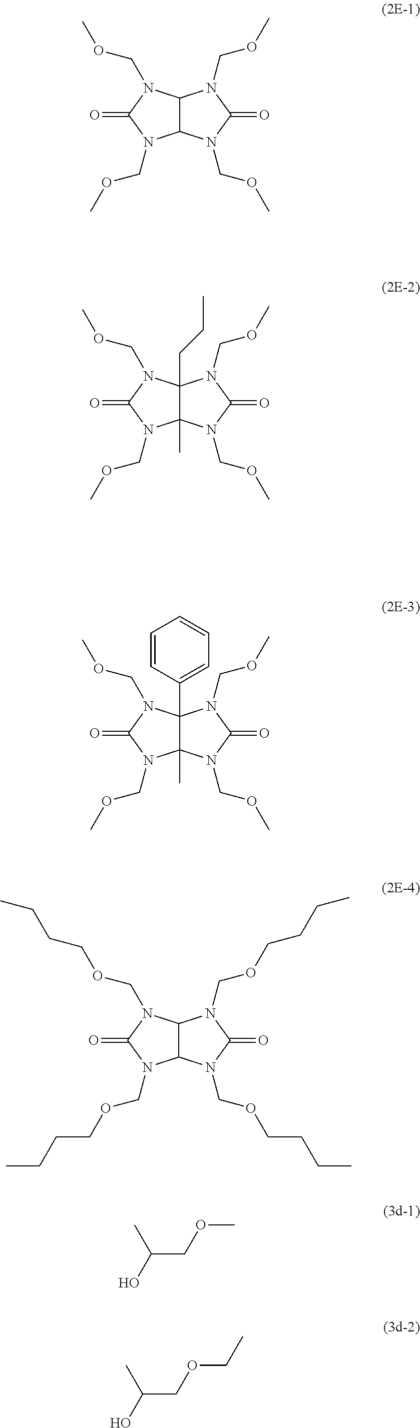

For the content related to a nitrogen-containing compound having 2 to 6 substituents represented by the formula (1d) which bond to a nitrogen atom in one molecule, the entire disclosure of WO2017/187969 A is incorporated herein by reference.

When a crosslinking agent is used, the content rate of the crosslinking agent is, for example, 1 mass % to 50 mass %, preferably 5 mass % to 30 mass& with respect to the polymer of the present invention.

### <Additive>

The protective-film forming composition of the present invention can contain, as an optional component, a compound that is at least one of a compound represented by the following formula (1a) and a compound represented by formula (1b) in order to improve adhesion properties between a protective film formed from the protective-film forming composition and a substrate.

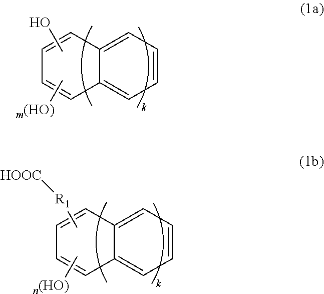

(In in the formulae (1a) and (1b), R₁ represents a single bond, an alkylene group having 1 to 4 carbon atoms, or an alkenylene group having 2 to 4 carbon atoms having one or two carbon-carbon double bonds; k represents 0 or 1; m represents an integer of 1 to 3; and n represents an integer of 2 to 4.)

Examples of the compound represented by the formula (1a) include compounds represented by the following formulas (1a-1) to (1a-19).

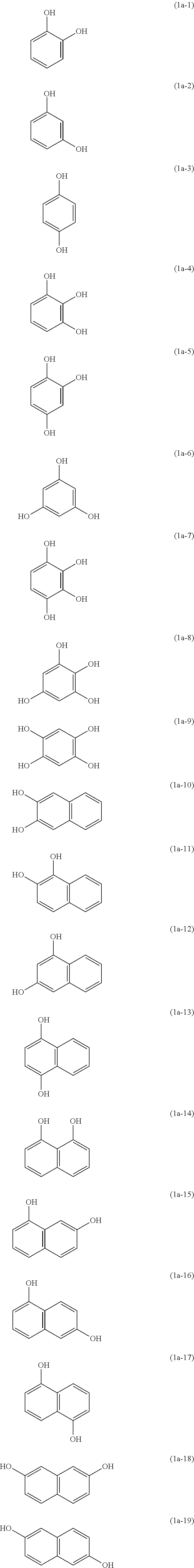

Examples of the compound represented by the formula (1b) include compounds represented by the following formulas (1b-1) to (1b-31).

[chemical structure]

When a compound that is at least one of the compound represented by the formula (1a) and the compound represented by the formula (1b) is used, the content rate of the compound with respect to the polymer of the present invention is, for example, 1 mass % to 50 mass %, preferably 1 mass % to 30 mass %, and more preferably 1 mass % to 10 mass %.

### <Acid Generator>

As the curing catalyst contained as an optional component in the protective-film forming composition, both a thermal acid generator and a photoacid generator can be used, but it is preferable to use a thermal acid generator.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (pyridinium p-phenolsulfonic acid salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyldiazomethane compound.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

Only one kind of curing catalyst can be used, or two or more kinds thereof can be used in combination.

When a curing catalyst is used, the content rate of the curing catalyst is, for example, 0.1 mass % to 50 mass %, preferably 1 mass % to 30 mass % with respect to the crosslinking agent.

### <Other Components>

In the protective-film forming composition, a surfactant can be further added in order to further improve the application properties for surface unevenness without occurrence of pinholes, striations, or the like. Examples of the surfactant include polyoxyethylene alkyl ethers such as polyoxyethylene lauryl ether, polyoxyethylene stearyl ether, polyoxyethylene cetyl ether and polyoxyethylene oleyl ether, polyoxyethylene alkyl allyl ethers such as polyoxyethylene octylphenol ether and polyoxyethylene nonylphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate and sorbitan tristearate, polyoxyethylene sorbitan monolaurate, polyoxyethylene sorbitan monopalmitate, polyoxyethylene sorbitan monostearate, polyoxyethylene sorbitan trioleate and polyoxyethylene sorbitan fatty acid esters such as polyoxyethylene sorbitan tristearate, F-top EF301, EF303, EF352 (Trade name, manufactured by TOCHEM PRODUCTS CO., LTD.), and polyoxyethylene sorbitan trioleate, Examples thereof include fluorine-based surfactants such as MEGAFACE F171, F173, R-30, and R-40 (Manufactured by DIC Corporation, trade name), Fluorad FC430 and FC431 (Trade name, manufactured by Sumitomo 3M Limited), AsahiGuard AG710, SURFLON S-382, SC101, SC102, SC103, SC104, SC105, and SC106 (Manufactured by AGC Inc., trade name), and organosiloxane polymer KP341 (manufactured by Shin-Etsu Chemical Co., Ltd.). The blending amount of these surfactants is usually 2.0 mass % or less, and preferably 1.0 mass % or less with respect to the total solid content of the protective-film forming composition. These surfactants may be added alone, or may be added in combination of two or more kinds thereof.

The nonvolatile content of the protective-film forming composition, that is, the component excluding the solvent is, for example, 0.01 mass % to 10 mass %.

(Protective Film, Method for Manufacturing Substrate with Protective Film, Method for Manufacturing Substrate with Resist Pattern, and Method for Manufacturing Semiconductor Device)

The protective film of the present invention is a baked product of an applied film made of a protective-film forming composition.

The method for manufacturing a substrate with a protective film of the present invention includes a step of forming a protective film by applying the protective-film forming composition of the present invention on a stepped semiconductor substrate and baking the composition.

The method for manufacturing a substrate with a resist pattern according to the present invention includes the following steps (1) to (2).

Step (1): a step of applying the protective-film forming composition of the present invention on a semiconductor substrate and baking the composition to form a protective film as a resist underlayer film.

Step (2): Step of forming a resist film on the protective film directly or via another layer, and then forming a resist pattern by exposure and development

A method for manufacturing a semiconductor device according to the present invention includes the following treatments (A) to (D).
Treatment (A): a treatment of forming a protective film using the protective-film forming composition of the present invention on a semiconductor substrate having an inorganic film formed on a surface thereof
Treatment (B): a treatment of forming a resist pattern on the protective film directly or via another layer
Treatment (C): a treatment of dry etching the protective film using the resist pattern as a mask to expose the surface of the inorganic film.
Treatment (D): a treatment of wet-etching the inorganic film using a wet etching solution for a semiconductor using the protective film after dry etching as a mask.

Examples of the semiconductor substrate to which the protective-film forming composition of the present invention is applied include silicon wafers, germanium wafers, and compound semiconductor wafers such as gallium arsenide, indium phosphide, gallium nitride, indium nitride, and aluminum nitride.

When a semiconductor substrate having an inorganic film formed on a surface thereof is used, the inorganic film is formed by, for example, an ALD (atomic layer deposition) method, a CVD (chemical vapor deposition) method, a reactive sputtering method, an ion plating method, a vacuum deposition method, or a spin coating (spin on glass: SOG) method. Examples of the inorganic film include a polysilicon film, a silicon oxide film, a silicon nitride film, a silicon oxynitride film, a BPSG (boro-phospho silicate glass) film, a titanium nitride film, a titanium oxynitride film, a tungsten nitride film, a gallium nitride film, and a gallium arsenide film.

The semiconductor substrate may be a stepped substrate in which so-called a via (hole), a trench (groove), and the like are formed. For example, the via has a substantially circular shape when viewed from the upper surface, the diameter of the substantially circular shape is, for example, 2 nm to 20 nm, and the depth is 50 nm to 500 nm, and the width of the trench (recess of the substrate) is, for example, 2 nm to 20 nm, and the depth is 50 nm to 500 nm.

Since the protective-film forming composition of the present invention has a small weight average molecular weight and average particle size of the compound contained in the composition, the composition can be embedded even in the stepped substrate as described above without defects such as voids (air spaces). It is an important characteristic that there is no defect such as a void for the next step (wet etching/dry etching of a semiconductor substrate, resist pattern formation) of semiconductor manufacturing.

The protective-film forming composition of the present invention is applied on such a semiconductor substrate by an appropriate application method such as a spinner or a coater. Thereafter, the protective film is formed by baking using a heating unit such as a hot plate. The baking conditions are appropriately selected from a baking temperature of 100° C. to 400° C. and a baking time of 0.3 minutes to 60 minutes. The baking temperature is preferably 120° C. to 350° C., and the baking time is 0.5 minutes to 30 minutes, more preferably 150° C. to 300° C., and the baking time is 0.8 minutes to 10 minutes. The thickness of the protective film to be formed is, for example, 0.001 μm to 10 μm, preferably 0.002 μm to 1 μm, and more preferably 0.005 μm to 0.5 μm. When the temperature at the time of baking is lower than the above range, crosslinking becomes insufficient, and resistance of the protective film to be formed to a resist solvent or a basic hydrogen peroxide aqueous solution may be difficult to obtain. On the other hand, when the temperature at the time of baking is higher than the above range, the protective film may be decomposed by heat.

A resist film is formed on the protective film directly or via another layer formed as described above, and then exposed and developed to form a resist pattern.

The exposure is performed through a mask (reticle) for forming a predetermined pattern, and for example, i-ray, KrF excimer laser, ArF excimer laser, EUV (extreme ultraviolet), or EB (electron beam) is used. An alkaline developer is used for development, and is appropriately selected from a development temperature of 5° C. to 50° C. and a development time of 10 seconds to 300 seconds. As the alkaline developer, for example, aqueous alkaline solutions of an inorganic alkali such as sodium hydroxide, potassium hydroxide, sodium carbonate, sodium silicate, sodium metasilicate, or ammonia water, a first amine such as ethylamine or n-propylamine, a second amine such as diethylamine or di-n-butylamine, a third amine such as triethylamine or methyldiethylamine, an alcoholamine such as dimethylethanolamine or triethanolamine, a quaternary ammonium salt such as tetramethylammonium hydroxide, tetraethylammonium hydroxide, or choline, or a cyclic amine such as pyrrole or piperidine can be used. Furthermore, it is also possible to add an appropriate amount of an alcohol such as isopropyl alcohol or a nonionic surfactant to the aqueous alkaline solution. Among them, preferred developers are quaternary ammonium salts, more preferably tetramethylammonium hydroxide and choline. Furthermore, a surfactant or the like can be added to these developers. In place of the alkaline developer, a method of performing development with an organic solvent such as butyl acetate and developing a part where the alkali dissolution rate of the photoresist is not improved can also be used.

Next, the protective film is dry-etched using the formed resist pattern as a mask. At that time, when the inorganic film is formed on the surface of the used semiconductor substrate, the surface of the inorganic film is exposed, and when the inorganic film is not formed on the surface of the used semiconductor substrate, the surface of the semiconductor substrate is exposed.

Further, a desired pattern is formed by wet etching using a wet etching solution for a semiconductor using the protective film (When a resist pattern remains on the protective film, the resist pattern is also formed on the protective film.) after dry etching as a mask.

As the wet etching solution for a semiconductor, a general chemical solution for etching a semiconductor wafer can be used, and for example, both a substance exhibiting acidity and a substance exhibiting basicity can be used.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, phosphoric acid, and a mixed solution thereof.

Examples of the substance exhibiting basicity include basic hydrogen peroxide water obtained by mixing an organic amine such as ammonia, sodium hydroxide, potassium hydroxide, sodium cyanide, potassium cyanide, or triethanolamine with hydrogen peroxide water to make the pH basic. Specific examples thereof include SC-1 (ammonia-hydrogen peroxide solution). In addition, those capable of making the pH basic, for example, those in which urea and hydrogen peroxide water are mixed to cause thermal decomposition of urea by heating to generate ammonia and finally make the pH basic, can also be used as a chemical solution for wet etching.

Among them, acidic hydrogen peroxide water or basic hydrogen peroxide water is preferable.

These chemical solutions may contain an additive such as a surfactant.

The use temperature of the wet etching solution for a semiconductor is desirably 25° C. to 90° C., and more desirably 40° C. to 80° C. The wet etching time is desirably 0.5 minutes to 30 minutes, and more desirably 1 minute to 20 minutes.

### EXAMPLES

Next, the contents of the present invention will be specifically described with reference to synthesis examples and examples, but the present invention is not limited thereto.

The weight average molecular weights of the polymers shown in Synthesis Examples 1 to 16 below are measurement results by gel permeation chromatography (Hereinafter, abbreviated as GPC). For the measurement, a GPC device manufactured by Tosoh Corporation was used, and measurement conditions and the like are as follows.
Column temperature: 40° C.
Flow rate: 0.35 ml/min
Eluent: tetrahydrofuran (THF)
Standard sample: polystyrene (Tosoh Corporation)

### Synthesis Example 1

To 3.74 g of monoallyl diglycidyl isocyanuric acid (product name: MA-DGIC, manufactured by SHIKOKU CHEMICALS CORPORATION), 2.10 g of EX-201 (Resorcinol diglycidyl ether, manufactured by Nagase ChemteX Corporation), 2.88 g of succinic acid (manufactured by Tokyo Chemical Industry Co., Ltd.) and 0.56 g of tetrabutylphosphonium bromide (manufactured by HOKKO CHEMICAL INDUSTRY CO., LTD.) in a reaction flask, 37.18 g of propylene glycol monomethyl ether was added. The resulting mixture was heated and stirred in a reaction flask at 105° C. for 16 hours under a nitrogen atmosphere. The obtained reaction product corresponded to the formula (x-1), and the weight average molecular weight Mw thereof measured in terms of polystyrene by GPC was 3700.

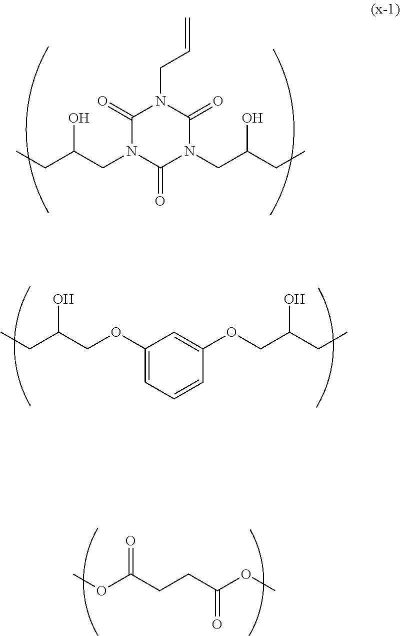

### Synthesis Example 2

To 2.17 g of monoallyl diglycidyl isocyanuric acid (product name: MA-DGIC, manufactured by SHIKOKU CHEMICALS CORPORATION), 1.50 g of EX-711 (manufactured by Nagase ChemteX Corporation), 1.67 g of succinic acid (manufactured by Tokyo Chemical Industry Co., Ltd.), and 0.32 g of tetrabutylphosphonium bromide (manufactured by HOKKO CHEMICAL INDUSTRY CO., LTD.) in a reaction flask, 22.69 g of propylene glycol monomethyl ether was added. The resulting mixture was heated and stirred in a reaction flask at 105° C. for 16 hours under a nitrogen atmosphere. The obtained reaction product corresponded to the formula (x-2), and the weight average molecular weight Mw thereof measured in terms of polystyrene by GPC was 4060.

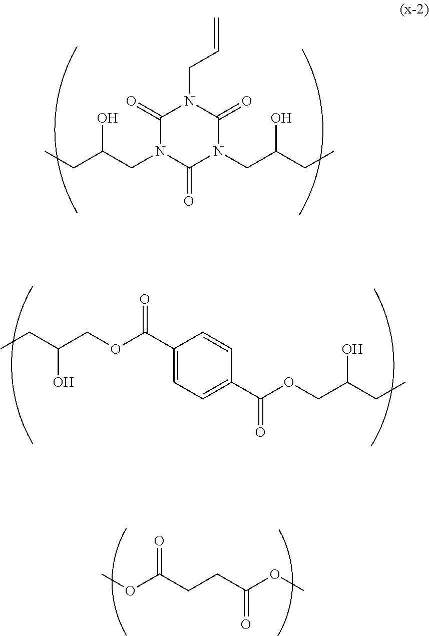

### Synthesis Example 3

To 2.10 g of monoallyl diglycidyl isocyanuric acid (product name: MA-DGIC, manufactured by SHIKOKU CHEMICALS CORPORATION), 1.60 g of EX-721 (manufactured by Nagase ChemteX Corporation), 1.62 g of succinic acid (manufactured by Tokyo Chemical Industry Co., Ltd.), and 0.31 g of tetrabutylphosphonium bromide (manufactured by HOKKO CHEMICAL INDUSTRY CO., LTD.) in a reaction flask, 22.57 g of propylene glycol monomethyl ether was added. The resulting mixture was heated and stirred in a reaction flask at 105° C. for 20 hours under a nitrogen atmosphere. The obtained reaction product corresponded to the formula (x-3), and the weight average molecular weight Mw thereof measured in terms of polystyrene by GPC was 3200.

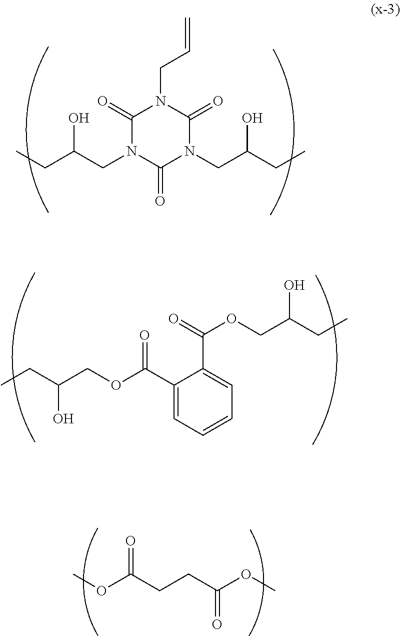

### Synthesis Example 4

To 2.21 g of monoallyl diglycidyl isocyanuric acid (product name: MA-DGIC, manufactured by SHIKOKU CHEMICALS CORPORATION), 1.50 g of HP-4032D (manufactured by DIC Corporation), 1.70 g of succinic acid (manufactured by Tokyo Chemical Industry Co., Ltd.) and 0.33 g of tetrabutylphosphonium bromide (manufactured by HOKKO CHEMICAL INDUSTRY CO., LTD.) in a reaction flask, 22.99 g of propylene glycol monomethyl ether was added. The resulting mixture was heated and stirred in a reaction flask at 105° C. for 16 hours under a nitrogen atmosphere. The obtained reaction product corresponded to the formula (x-4), and the weight average molecular weight Mw thereof measured in terms of polystyrene by GPC was 2700.

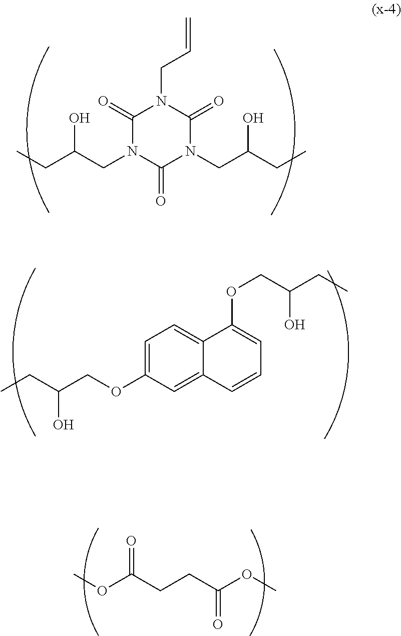

### Synthesis Example 5

To 1.50 g of monoallyl diglycidyl isocyanuric acid (product name: MA-DGIC, manufactured by SHIKOKU CHEMICALS CORPORATION), 1.87 g of RE-303S-L (manufactured by Nippon Kayaku Co., Ltd.), 1.44 g of succinic acid (manufactured by Tokyo Chemical Industry Co., Ltd.), and 0.28 g of tetrabutylphosphonium bromide (manufactured by HOKKO CHEMICAL INDUSTRY CO., LTD.) in a reaction flask, 20.39 g of propylene glycol monomethyl ether was added. The resulting mixture was heated and stirred in a reaction flask at 105° C. for 16 hours under a nitrogen atmosphere. The obtained reaction product corresponded to the formula (x-5), and the weight average molecular weight Mw thereof measured in terms of polystyrene by GPC was 3530.

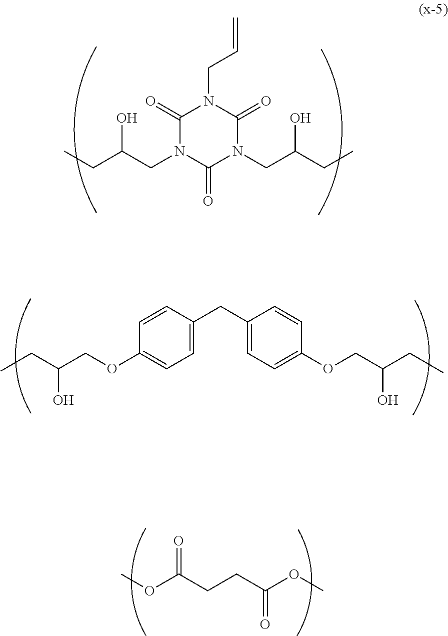

### Synthesis Example 6

To 1.80 g of monoallyl diglycidyl isocyanuric acid (product name: MA-DGIC, manufactured by SHIKOKU CHEMICALS CORPORATION), 1.87 g of RE-810NM (manufactured by Nippon Kayaku Co., Ltd.), 1.39 g of succinic acid (manufactured by Tokyo Chemical Industry Co., Ltd.), and 0.27 g of tetrabutylphosphonium bromide (manufactured by HOKKO CHEMICAL INDUSTRY CO., LTD.) in a reaction flask, 21.34 g of propylene glycol monomethyl ether was added. The resulting mixture was heated and stirred in a reaction flask at 105° C. for 20 hours under a nitrogen atmosphere. The obtained reaction product corresponded to the formula (x-6), and the weight average molecular weight Mw thereof measured in terms of polystyrene by GPC was 3910.

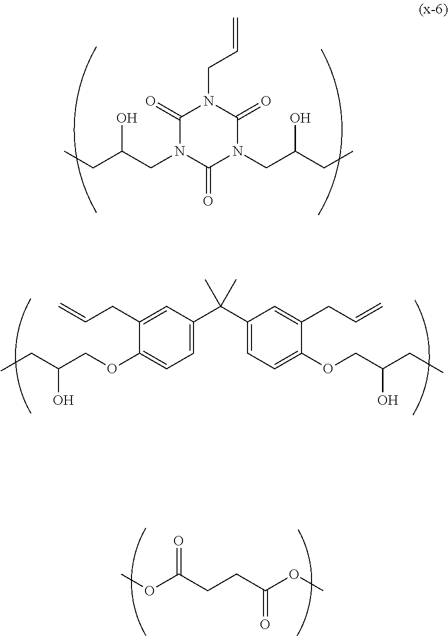

### Synthesis Example 7

To 11.19 g of a propylene glycol monomethyl ether solution of monomethyl diglycidyl isocyanuric acid (product name: Me-DGIC, manufactured by SHIKOKU CHEMICALS CORPORATION, solid content: 30 mass %), 2.10 g of EX-201 (manufactured by Nagase ChemteX Corporation), 2.88 g of succinic acid (manufactured by Tokyo Chemical Industry Co., Ltd.), and 0.56 g of tetrabutylphosphonium bromide (manufactured by HOKKO CHEMICAL INDUSTRY CO., LTD.) in the reaction flask, 27.76 g of propylene glycol monomethyl ether was added. The resulting mixture was heated and stirred in a reaction flask at 105° C. for 16 hours under a nitrogen atmosphere. The obtained reaction product corresponded to the formula (x-7), and the weight average molecular weight Mw thereof measured in terms of polystyrene by GPC was 2400.

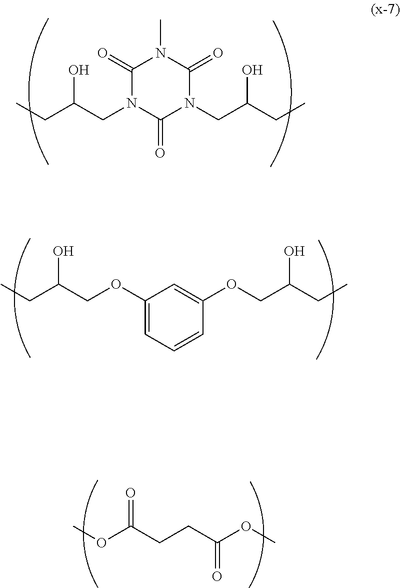

### Synthesis Example 8

To 6.50 g of a propylene glycol monomethyl ether solution of monomethyl diglycidyl isocyanuric acid (product name: Me-DGIC, manufactured by SHIKOKU CHEMICALS CORPORATION, solid content: 30 mass %), 1.50 g of EX-711 (manufactured by Nagase ChemteX Corporation), 1.67 g of succinic acid (manufactured by Tokyo Chemical Industry Co., Ltd.), and 0.32 g of tetrabutylphosphonium bromide (manufactured by HOKKO CHEMICAL INDUSTRY CO., LTD.) in the reaction flask, 17.24 g of propylene glycol monomethyl ether was added. The resulting mixture was heated and stirred in a reaction flask at 105° C. for 22 hours under a nitrogen atmosphere. The obtained reaction product corresponded to the formula (x-8), and the weight average molecular weight Mw thereof measured in terms of polystyrene by GPC was 2430.

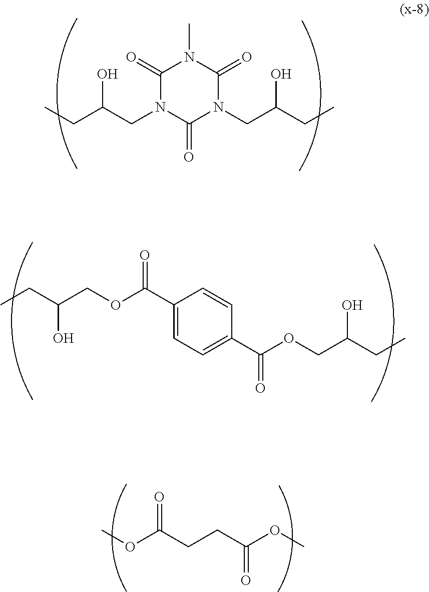

### Synthesis Example 9

To 6.00 g of a propylene glycol monomethyl ether solution of monomethyl diglycidyl isocyanuric acid (product name: Me-DGIC, manufactured by SHIKOKU CHEMICALS CORPORATION, solid content: 30 mass %), 1.52 g of EX-721 (manufactured by Nagase ChemteX Corporation), 1.54 g of succinic acid (manufactured by Tokyo Chemical Industry Co., Ltd.), and 0.30 g of tetrabutylphosphonium bromide (manufactured by HOKKO CHEMICAL INDUSTRY CO., LTD.) in the reaction flask, 16.47 g of propylene glycol monomethyl ether was added. The resulting mixture was heated and stirred in a reaction flask at 105° C. for 20 hours under a nitrogen atmosphere. The obtained reaction product corresponded to the formula (x-9), and the weight average molecular weight Mw thereof measured in terms of polystyrene by GPC was 1770.

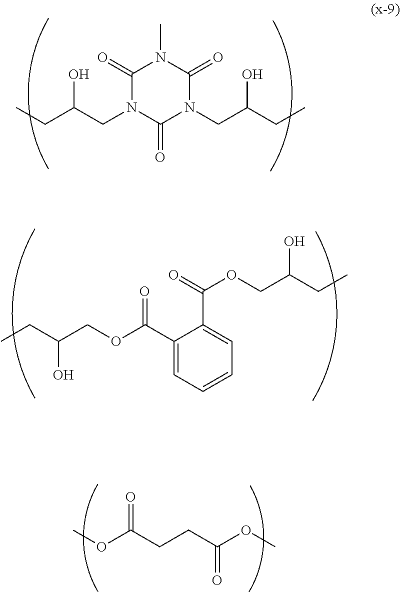

### Synthesis Example 10

To 8.81 g of a propylene glycol monomethyl ether solution of monomethyl diglycidyl isocyanuric acid (product name: Me-DGIC, manufactured by SHIKOKU CHEMICALS CORPORATION, solid content: 30 mass %), 2.00 g of HP-4032D (manufactured by DIC Corporation), 2.27 g of succinic acid (manufactured by Tokyo Chemical Industry Co., Ltd.), and 0.44 g of tetrabutylphosphonium bromide (manufactured by HOKKO CHEMICAL INDUSTRY CO., LTD.) in the reaction flask, 23.24 g of propylene glycol monomethyl ether was added. The resulting mixture was heated and stirred in a reaction flask at 105° C. for 21 hours under a nitrogen atmosphere. The obtained reaction product corresponded to the formula (x-10), and the weight average molecular weight Mw thereof measured in terms of polystyrene by GPC was 2350.

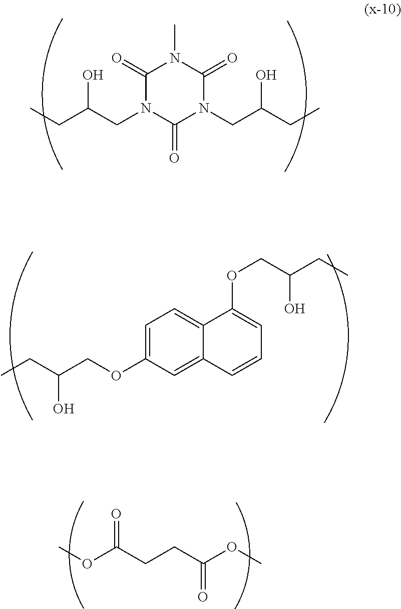

### Synthesis Example 11

To 6.00 g of a propylene glycol monomethyl ether solution of monomethyl diglycidyl isocyanuric acid (product name: Me-DGIC, manufactured by SHIKOKU CHEMICALS CORPORATION, solid content: 30 mass %), 1.60 g of RE-303S-L (manufactured by Nippon Kayaku Co., Ltd.), 1.54 g of succinic acid (manufactured by Tokyo Chemical Industry Co., Ltd.), and 0.30 g of tetrabutylphosphonium bromide (manufactured by HOKKO CHEMICAL INDUSTRY CO., LTD.) in a reaction flask, 16.80 g of propylene glycol monomethyl ether was added. The resulting mixture was heated and stirred in a reaction flask at 105° C. for 23 hours under a nitrogen atmosphere. The obtained reaction product corresponded to the formula (x-11), and the weight average molecular weight Mw thereof measured in terms of polystyrene by GPC was 2850.

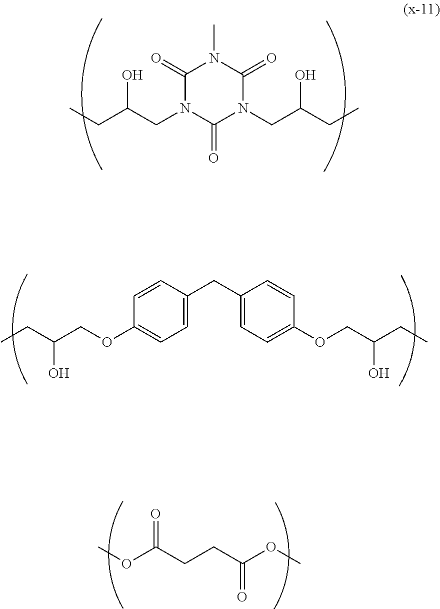

### Synthesis Example 12

To 5.50 g of a propylene glycol monomethyl ether solution of monomethyl diglycidyl isocyanuric acid (product name: Me-DGIC, manufactured by SHIKOKU CHEMICALS CORPORATION, solid content: 30 mass %), 1.91 g of RE-810NM (manufactured by Nippon Kayaku Co., Ltd.), 1.41 g of succinic acid (manufactured by Tokyo Chemical Industry Co., Ltd.), and 0.27 g of tetrabutylphosphonium bromide (manufactured by HOKKO CHEMICAL INDUSTRY CO., LTD.) in a reaction flask, 17.16 g of propylene glycol monomethyl ether was added. The resulting mixture was heated and stirred in a reaction flask at 105° C. for 20 hours under a nitrogen atmosphere. The obtained reaction product corresponded to the formula (x-12), and the weight average molecular weight Mw thereof measured in terms of polystyrene by GPC was 3450.

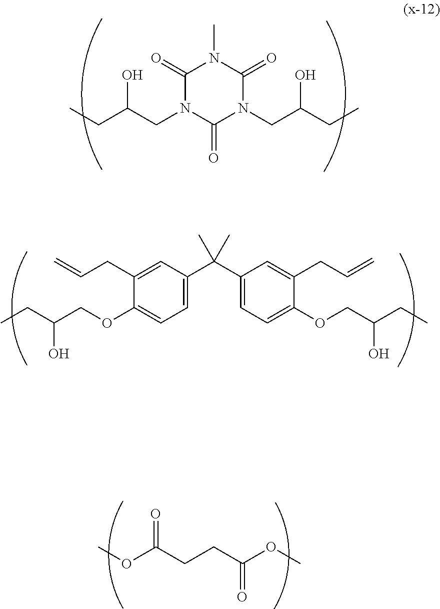

### Synthesis Example 13

To 3.06 g of a propylene glycol monomethyl ether solution of monoallyl diglycidyl isocyanuric acid (product name: MA-DGIC, manufactured by SHIKOKU CHEMICALS CORPORATION, solid content: 30 mass %), 2.00 g of HP-4032D (manufactured by DIC Corporation), 2.64 g of glutaric acid (manufactured by Tokyo Chemical Industry Co., Ltd.), and 0.46 g of tetrabutylphosphonium bromide (manufactured by HOKKO CHEMICAL INDUSTRY CO., LTD.) in a reaction flask, 32.69 g of propylene glycol monomethyl ether was added. The resulting mixture was heated and stirred in a reaction flask at 105° C. for 20 hours under a nitrogen atmosphere. The obtained reaction product corresponded to the formula (x-13), and the weight average molecular weight Mw thereof measured in terms of polystyrene by GPC was 5200.

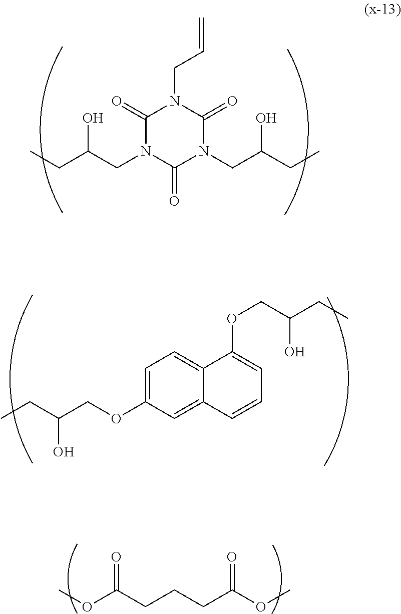

### Synthesis Example 14

To 1.85 g of monoallyl diglycidyl isocyanuric acid (product name: MA-DGIC, manufactured by SHIKOKU CHEMICALS CORPORATION), 1.30 g of EX-216L (manufactured by Nagase ChemteX Corporation), 1.43 g of succinic acid (manufactured by Tokyo Chemical Industry Co., Ltd.), and 0.28 g of tetrabutylphosphonium bromide (manufactured by HOKKO CHEMICAL INDUSTRY CO., LTD.) in a reaction flask, 19.46 g of propylene glycol monomethyl ether was added. The resulting mixture was heated and stirred in a reaction flask at 105° C. for 23 hours under a nitrogen atmosphere. The obtained reaction product corresponded to the formula (x-14), and the weight average molecular weight Mw thereof measured in terms of polystyrene by GPC was 2490.

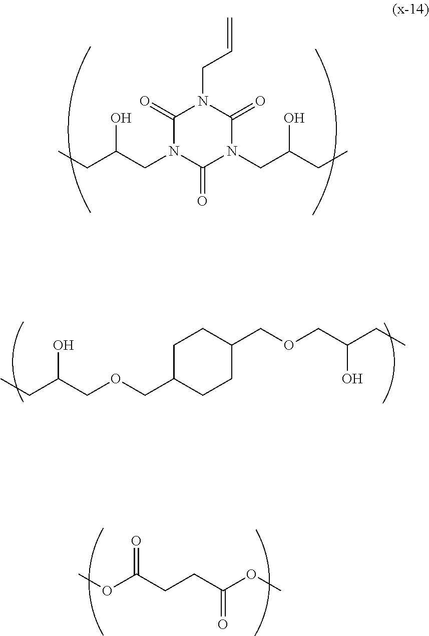

### Synthesis Example 15

To 1.82 g of monoallyl diglycidyl isocyanuric acid (product name: MA-DGIC, manufactured by SHIKOKU CHEMICALS CORPORATION), 1.60 g of EX-722L (manufactured by Nagase ChemteX Corporation), 1.41 g of succinic acid (manufactured by Tokyo Chemical Industry Co., Ltd.), and 0.27 g of tetrabutylphosphonium bromide (manufactured by HOKKO CHEMICAL INDUSTRY CO., LTD.) in a reaction flask, 20.45 g of propylene glycol monomethyl ether was added. The resulting mixture was heated and stirred in a reaction flask at 105° C. for 16 hours under a nitrogen atmosphere. The obtained reaction product corresponded to the formula (x-15), and the weight average molecular weight Mw thereof measured in terms of polystyrene by GPC was 1570.

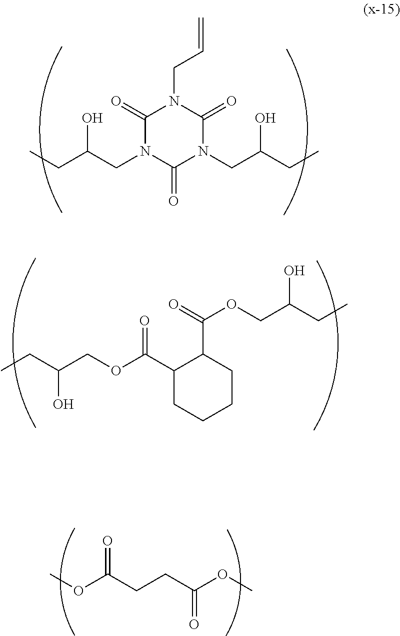

### Synthesis Example 16

To 1.93 g of monoallyl diglycidyl isocyanuric acid (product name: MA-DGIC, manufactured by SHIKOKU CHEMICALS CORPORATION), 2.00 g of EX-252 (manufactured by Nagase ChemteX Corporation), 1.49 g of succinic acid (manufactured by Tokyo Chemical Industry Co., Ltd.), and 0.29 g of tetrabutylphosphonium bromide (manufactured by HOKKO CHEMICAL INDUSTRY CO., LTD.) in a reaction flask, 22.90 g of propylene glycol monomethyl ether was added. The resulting mixture was heated and stirred in a reaction flask at 105° C. for 20 hours under a nitrogen atmosphere. The obtained reaction product corresponded to the formula (x-16), and the weight average molecular weight Mw thereof measured in terms of polystyrene by GPC was 2970.

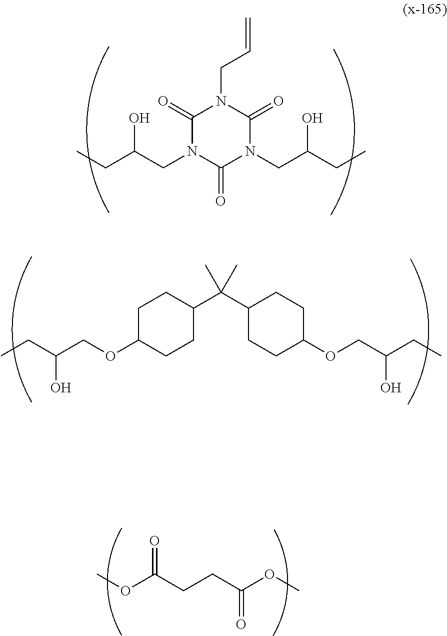

### Synthesis Example 17

A polymer having the same composition as the reaction product synthesized in Synthesis Example 3 of WO2018/203540 A was synthesized. The synthesis method is shown below.

To 2.29 g of monoallyl diglycidyl isocyanuric acid (product name: MA-DGIC, manufactured by SHIKOKU CHEMICALS CORPORATION), 1.50 g of HP-4032D (manufactured by DIC Corporation), 3.15 g of 3,3′-dithiodipropionic acid (manufactured by Tokyo Chemical Industry Co., Ltd.), and 0.34 g of tetrabutylphosphonium bromide (manufactured by HOKKO CHEMICAL INDUSTRY CO., LTD.) in a reaction flask, 29.21 g of propylene glycol monomethyl ether was added. The resulting mixture was heated and stirred in a reaction flask at 105° C. for 20 hours under a nitrogen atmosphere. The obtained reaction product corresponded to the formula (In), and the weight average molecular weight Mw thereof measured in terms of polystyrene by GPC was 4500.

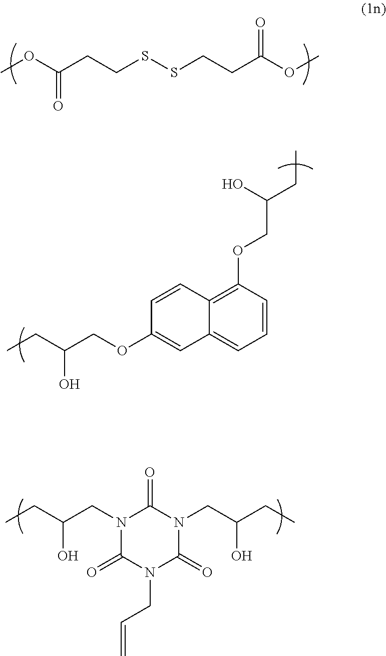

### Synthesis Example 18

A polymer having the same composition as the reaction product synthesized in Synthesis Example 6 of WO2018/203540 A was synthesized. The synthesis method is shown below.

To 1.03 g of ethylene glycol glycidyl ether (product name: EPOLITE 40E, manufactured by Kyoeisha Chemical Co., Ltd.), 2.00 g of RE-303S-L (manufactured by Nippon Kayaku Co., Ltd.), 2.40 g of monoallyl isocyanurate (product name: MAICA, manufactured by SHIKOKU CHEMICALS CORPORATION), 0.30 g of tetrabutylphosphonium bromide (manufactured by HOKKO CHEMICAL INDUSTRY CO., LTD.), and 0.06 g of hydroquinone (manufactured by Tokyo Chemical Industry Co., Ltd.) in a reaction flask, 23.21 g of propylene glycol monomethyl ether was added. The resulting mixture was heated and stirred in a reaction flask at 105° C. for 22 hours under a nitrogen atmosphere. The obtained reaction product corresponded to the formula (1 m), and the weight average molecular weight Mw thereof measured in terms of polystyrene by GPC was 5080.

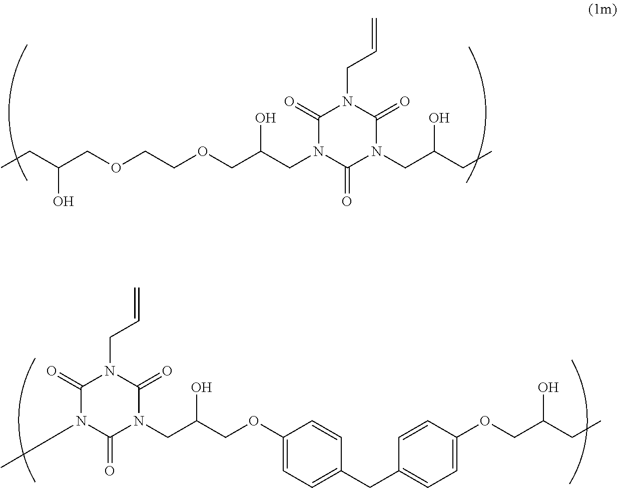

The molar ratio of the monomer components in Synthesis Examples 1 to 16 is shown in Table 1.

TABLE 1

| | Molar ratio |
|---|---|
| Synthesis | MA-DGIC/EX-201/SA = |
| Example 1 | 60/40/110 |
| Synthesis | MA-DGIC/EX-711/SA = |
| Example 2 | 60/40/110 |
| Synthesis | MA-DGIC/EX-721/SA = |
| Example 3 | 60/40/110 |
| Synthesis | MA-DGIC/HP-4032D/SA = |
| Example 4 | 60/40/110 |
| Synthesis | MA-DGIC/RE-303S-L/SA = |
| Example 5 | 60/40/110 |
| Synthesis | MA-DGIC/RE-810NM/SA = |
| Example 6 | 60/40/110 |
| Synthesis | Me-DGIC/EX-201/SA = |
| Example 7 | 60/40/110 |
| Synthesis | Me-DGIC/EX-711/SA = |
| Example 8 | 60/40/110 |
| Synthesis | Me-DGIC/EX-721/SA = |
| Example 9 | 60/40/110 |
| Synthesis | Me-DGIC/HP-4032D/SA = |
| Example 10 | 60/40/110 |
| Synthesis | Me-DGIC/RE-303S-L/SA = |
| Example 11 | 60/40/110 |
| Synthesis | Me-DGIC/RE-810NM/SA = |
| Example 12 | 60/40/110 |
| Synthesis | MA-DGIC/HP-4032D/GTA = |
| Example 13 | 60/40/110 |
| Synthesis | MA-DGIC/EX-216L/SA = |
| Example 14 | 60/40/110 |
| Synthesis | MA-DGIC/EX-722L/SA = |
| Example 15 | 60/40/110 |
| Synthesis | MA-DGIC/EX-262/SA = |
| Example 16 | 60/40/110 |

In Table 1, SA represents succinic acid, and GTA represents glutaric acid.

### Example 1

To 7.25 g of a propylene glycol monomethyl ether solution (solid content: 18.9 mass) of the reaction product corresponding to formula (x-1), which was obtained in Synthesis Example 1, 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.71 g of propylene glycol monomethyl ether, and 2.84 g of propylene glycol monomethyl ether acetate were added to obtain a solution. The solution was filtered through a polyethylene microfilter having a pore size of 0.02 μm to prepare a protective-film forming composition.

### Example 2

To 7.65 g of a propylene glycol monomethyl ether solution (solid content: 17.9 mass %) of the reaction product corresponding to the above formula (x-2), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.31 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 3

To 7.57 g of a propylene glycol monomethyl ether solution (solid content: 18.1 mass %) of the reaction product corresponding to the above formula (x-3), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.39 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 4

To 7.96 g of a propylene glycol monomethyl ether solution (solid content: 17.2 mass %) of the reaction product corresponding to the above formula (x-4), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.99 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 5

To 8.25 g of a propylene glycol monomethyl ether solution (solid content: 16.6 mass %) of the reaction product corresponding to the above formula (x-5), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.71 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 6

To 8.40 g of a propylene glycol monomethyl ether solution (solid content: 16.3 mass %) of the reaction product corresponding to the above formula (x-6), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.55 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 7

To 7.36 g of a propylene glycol monomethyl ether solution (solid content: 18.6 mass %) of the reaction product corresponding to the above formula (x-7), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.59 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 8

To 7.74 g of a propylene glycol monomethyl ether solution (solid content: 17.7 mass %) of the reaction product corresponding to the above formula (x-8), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.22 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 9

To 7.48 g of a propylene glycol monomethyl ether solution (solid content: 18.3 mass %) of the reaction product corresponding to the above formula (x-9), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.47 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 10

To 8.06 g of a propylene glycol monomethyl ether solution (solid content: 17.0 mass %) of the reaction product corresponding to the above formula (x-10), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.90 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 11

To 8.40 g of a propylene glycol monomethyl ether solution (solid content: 16.3 mass %) of the reaction product corresponding to the above formula (x-11), 0.26 g of 3,3′,5,5′-tetrakis(methoxymethyl)-4,4′-dihydroxybiphenyl (product name: TMOM-BP, manufactured by Honshu Chemical Industry Co., Ltd.), 0.04 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.55 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 12

To 8.20 g of a propylene glycol monomethyl ether solution (solid content: 16.7 mass %) of the reaction product corresponding to the above formula (x-12), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.76 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 13

To 7.78 g of a propylene glycol monomethyl ether solution (solid content: 17.6 mass %) of the reaction product corresponding to the above formula (x-13), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.18 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 14

To 8.10 g of a propylene glycol monomethyl ether solution (solid content: 16.9 mass %) of the reaction product corresponding to the above formula (x-14), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.85 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 15

To 8.06 g of a propylene glycol monomethyl ether solution (solid content: 17.0 mass %) of the reaction product corresponding to the above formula (x-15), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.90 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 16

To 8.10 g of a propylene glycol monomethyl ether solution (solid content: 16.9 mass %) of the reaction product corresponding to the above formula (x-16), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.85 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Example 17

To 7.76 g of a propylene glycol monomethyl ether solution (solid content: 17.2 mass %) of the reaction product corresponding to the above formula (x-4), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.04 g of gallic acid, 0.01 g of a surfactant (product name: MEGAFACE R-40, manufactured by DIC Corporation), 19.16 g of propylene glycol monomethyl ether, and 2.84 g of propylene glycol monomethyl ether acetate were added to 7.76 g of a propylene glycol monomethyl ether solution (solid content: 17.2 mass %) of the reaction product corresponding to the formula (x-4) to obtain a solution. The solution was filtered through a polyethylene microfilter having a pore size of 0.02 μm to prepare a protective-film forming composition.

### Comparative Example 1

To 8.25 g of a propylene glycol monomethyl ether solution (solid content: 16.4 mass %) of a reaction product corresponding to the formula (1n), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 18.05 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### Comparative Example 2

To 7.87 g of a propylene glycol monomethyl ether solution (solid content: 17.4 mass %) of the reaction product corresponding to the formula (1 m), 0.13 g of 3,3′,5,5′-tetrakis(methoxymethyl)-4,4′-dihydroxybiphenyl (product name: TMOM-BP, manufactured by Honshu Chemical Industry Co., Ltd.), 0.05 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 19.09 g of propylene glycol monomethyl ether, and 2.84 g of propylene glycol monomethyl ether acetate were added to prepare a solution. The solution was filtered through a polyethylene microfilter having a pore size of 0.02 μm to prepare a protective-film forming composition.

### [Resist Solvent Resistance Test]

Each of the protective-film forming compositions prepared in Examples 1 to 17 and Comparative Examples 1 and 2 was applied (spin-coated) on a silicon wafer with a spin coater. The applied silicon wafer was heated on a hot plate at 220° C. for 1 minute to form a coating (protective film) having a thickness of 150 nm. Next, in order to confirm solvent resistance of the protective film, the silicon wafer on which the protective film had been formed was immersed for 1 minute in a mixed solvent obtained by mixing propylene glycol monomethyl ether and propylene glycol monomethyl ether acetate at a mass ratio of 7:3, spin-dried, and then baked at 100° C. for 30 seconds. The film thickness of the protective film before and after immersion in the mixed solvent was measured with a light interference film thickness meter (product name: NanoSpec 6100, manufactured by Nanometrics Inc.).

In the evaluation of solvent resistance, the film thickness reduction rate (%) of the protective film removed by solvent immersion was calculated and evaluated from the following calculation formula.

Film thickness reduction rate (%)=((A−B)÷A)×100
A: Film thickness before solvent immersion
B: Film thickness after solvent immersion

The results are shown in Table 2. When the film thickness reduction rate is about 1% or less, it can be said that the film has sufficient solvent resistance.

TABLE 2

| | Film thickness reduction rate |
|---|---|
| Example 1 | 0.1% |
| Example 2 | 0.0% |
| Example 3 | 0.0% |
| Example 4 | 0.0% |
| Example 5 | 0.2% |
| Example 6 | 0.1% |
| Example 7 | 0.1% |
| Example 8 | 0.0% |
| Example 9 | 0.0% |
| Example 10 | 0.0% |
| Example 11 | 0.1% |
| Example 12 | 0.1% |
| Example 13 | 0.0% |
| Example 14 | 0.1% |
| Example 15 | 0.2% |
| Example 16 | 0.2% |
| Example 17 | 0.0% |
| Comparative | 0.1% |
| Example 1 | |
| Comparative | 0.1% |
| Example 2 | |

From the above results, the film thickness change of the protective-film forming compositions of Examples 1 to 17 and Comparative Examples 1 to 2 was very small even after immersion in the solvent. Therefore, the protective-film forming compositions of Examples 1 to 17 have sufficient solvent resistance to function as a protective film.

### [Resistance Test to Hydrogen Peroxide Water]

As an evaluation of resistance to hydrogen peroxide water, each of the protective-film forming compositions prepared in Examples 1 to 17 and Comparative Examples 1 and 2 was applied to a titanium nitride (TiN) vapor deposition substrate having a film thickness of 50 nm, and heated at 220° C. for 1 minute to form a protective film having a film thickness of 150 nm. Next, 20 mass % hydrogen peroxide was prepared. The TiN deposited substrate applied with the protective-film forming composition was immersed in this 20 mass % hydrogen peroxide water heated to 70° C., and the time from immediately after the immersion until the film (protective film) was fogged or damaged was measured. The results of the resistance test to hydrogen peroxide water are shown in Table 3. It can be said that the longer the resistance time, the higher the resistance to the wet etching solution using the hydrogen peroxide solution.

TABLE 3

| | Resistance time of protective film |
|---|---|
| Example 1 | 200 seconds |
| Example 2 | 280 seconds |
| Example 3 | 230 seconds |
| Example 4 | 180 seconds |
| Example 5 | 200 seconds |
| Example 6 | 200 seconds |
| Example 7 | 180 seconds |
| Example 8 | 280 seconds |
| Example 9 | 200 seconds |
| Example 10 | 180 seconds |
| Example 11 | 180 seconds |
| Example 12 | 180 seconds |
| Example 13 | 260 seconds |
| Example 14 | 180 seconds |
| Example 15 | 200 seconds |
| Example 16 | 200 seconds |
| Example 17 | 290 seconds |
| Comparative | 50 seconds |
| Example 1 | |
| Comparative | 100 seconds |
| Example 2 | |

From the results in the above table, it was shown that the films produced using the protective-film forming compositions prepared in Examples 1 to 17 have sufficient resistance to the hydrogen peroxide aqueous solution. That is, it was found that these films can serve as a protective film against the hydrogen peroxide aqueous solution. In addition, it can be said that better resistance to a wet etching solution using a hydrogen peroxide solution is exhibited as compared with Comparative Examples 1 and 2. Therefore, Examples 1 to 17 have better chemical solution resistance to hydrogen peroxide water as compared with Comparative Examples 1 and 2, and thus are useful as protective films against a wet etching solution for a semiconductor.

### [Measurement of Sublimate Amount]

The measurement of the sublimate amount was performed using a sublimate amount measuring apparatus described in WO 2007/111147 A.

Protective-film forming compositions prepared in Examples 1 to 7, Example 9, Example 11, Example 12, Example 15, Example 17, and Comparative Examples 1 to 2 were applied to a silicon wafer substrate having a diameter of 4 inches so that the film thickness of the protective film to be obtained was 150 nm.

The wafer applied with the protective-film forming composition was set in the sublimate amount measurement device integrated with a hot plate, and baked for 60 seconds, and the sublimate was collected on a QCM (Quartz Crystal Microbalance) sensor, that is, a quartz resonator on which an electrode was formed. The QCM sensor can measure a small amount of mass change by utilizing a property that a frequency of the quartz resonator changes (lowers) according to a mass of a sublimate attached to a surface (electrode) of the quartz resonator.

The detailed measurement procedure is as follows. The temperature of the hot plate of the sublimate amount measurement device was raised to the measurement temperature (baking temperature) described in Table 4, the pump flow rate was set to 2.4 m³/s, and the device was left for the first 60 seconds for stabilization of the device. Immediately thereafter, the wafer coated with the protective-film forming composition was rapidly placed on a hot plate from the slide port, and the sublimate was collected at the time point of 120 seconds (60 seconds) from the time point of 60 seconds. The flow attachment (detection part) serving as a connection between the QCM sensor and the collection funnel part of the sublimate amount measurement device is used without a nozzle, and therefore an airflow flows in from a flow path (diameter: 32 mm) of a chamber unit having a distance from the sensor (quartz resonator) of 30 mm without being narrowed. In the QCM sensor, a material (AlSi) containing silicon and aluminum as main components was used as an electrode, the diameter (sensor diameter) of the quartz resonator was 14 mm, the electrode diameter on the surface of the quartz resonator was 5 mm, and the resonance frequency was 9 MHz.

The obtained frequency change was converted from the eigenvalue of the quartz resonator used for measurement to a gram, and the relationship between the amount of sublimate of one wafer applied with the protective-film forming composition and the lapse of time was clarified. The first 60 seconds are a time zone during which the wafer is left for apparatus stabilization (no wafer is set), and the measurement value from the time point of 60 seconds when the wafer is placed on the hot plate to the time point of 120 seconds is the measurement value related to the sublimate amount of the wafer. The sublimate amount of the protective film quantified from the device is shown in Table 4 as a sublimate amount ratio. The sublimate amount is represented by a relative value obtained by converting the value in Comparative Example 1 to 1.00.

TABLE 4

| | | Sublimate amount |
|---|---|---|
| | | (converting the |
| | Baking | value in Comparative |
| | temperature | Example 1 to 1.00) |
| Example 1 | 220° C. | 0.57 |
| Example 2 | 220° C. | 0.44 |
| Example 3 | 220° C. | 0.50 |
| Example 4 | 220° C. | 0.40 |
| Example 5 | 220° C. | 0.41 |
| Example 6 | 220° C. | 0.86 |
| Example 7 | 220° C. | 0.74 |
| Example 9 | 220° C. | 0.90 |
| Example 11 | 220° C. | 0.77 |
| Example 12 | 220° C. | 0.92 |
| Example 15 | 220° C. | 0.98 |
| Example 17 | 220° C. | 0.50 |
| Comparative Example 1 | 220° C. | 1.00 |
| Comparative Example 2 | 220° C. | 2.27 |

### [Evaluation of Embedding Properties in Substrate]

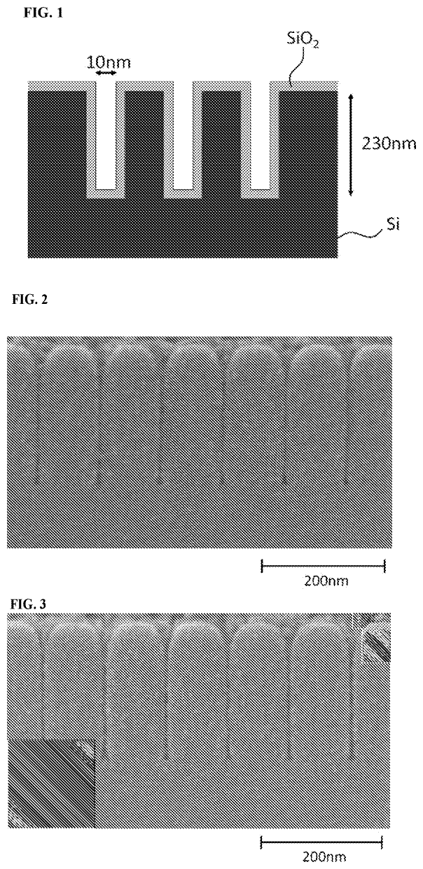

Each protective-film forming composition of Examples 1, 2, 4, 7, 8, and 10 and Comparative Example 1 was applied on a silicon processed substrate (after silicon oxide film deposition: 10 nm trench (L (line)/S (space)) in which a silicon oxide film was formed on a trench surface part, which was prepared by depositing a silicon oxide film of about 20 nm by a CVD (chemical vapor deposition) method on a silicon substrate in which a 50 nm trench (L (line)/S (space)) was formed. Thereafter, heating was performed on a hot plate at 220° C. for 1 minute to form a protective film having a film thickness of about 150 nm. Using a scanning electron microscope (SEM), the cross-sectional shape (FIG. 1) of the substrate having the trench in which the protective film was formed was observed to evaluate embedding properties.

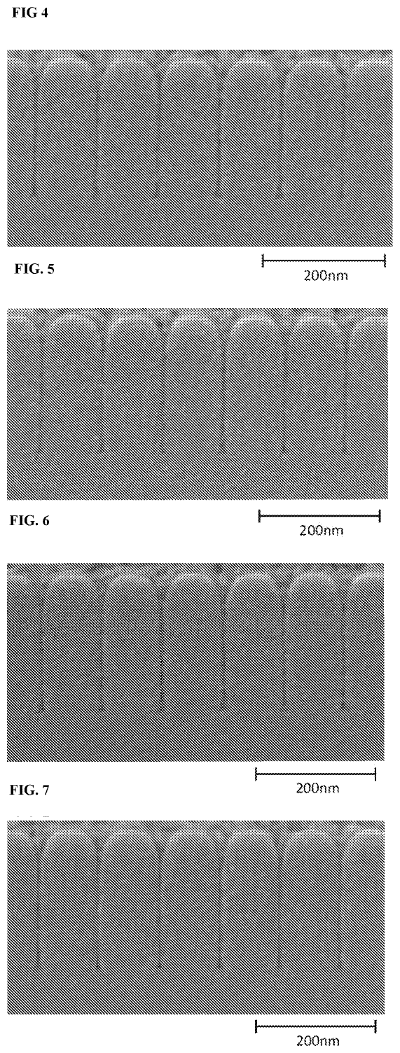

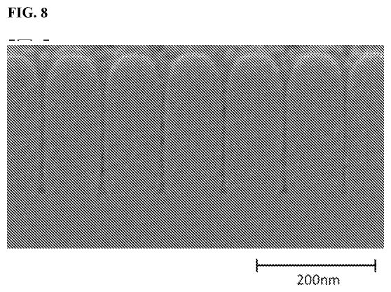

In the protective-film forming compositions of evaluated Examples 1, 2, 4, 7, 8, and 10 and Comparative Example 1, it can be seen that the composition is embedded in a 10 nm trench (L (line)/S (space)) substrate which is a gap between silicon oxide films without generating a void (air space and the like) (FIGS. 2 to 8).

1. A polymer having a partial structure represented by the following formula (1), a partial structure represented by the following formula (2), and a partial structure represented by the following formula (3): 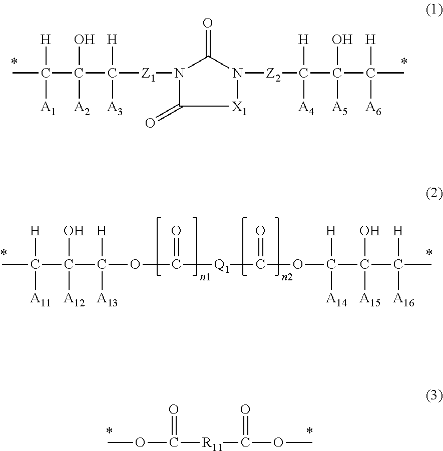
wherein in the formula (1), X₁ represents a divalent group represented by the following formula (1-1), formula (1-2), or formula (1-3); Z₁ and Z₂ each independently represent a direct bond or a divalent group represented by the following formula (1-4); A₁, A₂, A₃, A₄, A₅, and A₆ each independently represent a hydrogen atom, a methyl group, or an ethyl group; and * represents a bond;
in the formula (2), Q₁ represents a divalent organic group having an aromatic hydrocarbon ring or an aliphatic hydrocarbon ring; A₁₁, A₁₂, A₁₃, A₁₄, A₁₅, and A₁₆ each independently represent a hydrogen atom, a methyl group, or an ethyl group; and n1 and n2 each independently represent 0 or 1; * represents a bond;
in the formula (3), R₁₁ represents an alkylene group having 1 to 10 carbon atoms; and * represents a bond; 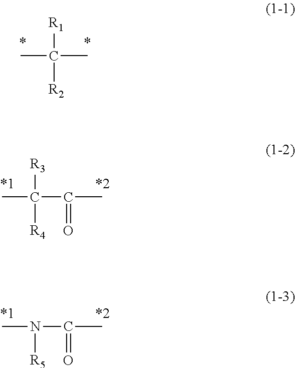
in the formulae (1-1) to (1-3), R₁ to R₅ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group or a phenyl group, and the phenyl group may be substituted by at least one monovalent group selected from the group consisting of an alkyl group having 1 to 6 carbon atoms, a halogen atom, an alkoxy group having 1 to 6 carbon atoms, a nitro group, a cyano group and an alkylthio group having 1 to 6 carbon atoms; R₁ and R₂ may be bonded to each other to form a ring having 3 to 6 carbon atoms; R₃ and R₄ may be bonded to each other to form a ring having 3 to 6 carbon atoms;* represents a bond; * 1 represents a bond bonded to a carbon atom; and *2 represents a bond bonded to a nitrogen atom; and 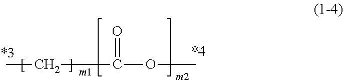
in the formula (1-4), m1 is an integer of 1 to 4; m2 is 0 or 1; * 3 represents a bond bonded to a nitrogen atom; and *4 represents a bond bonded to a carbon atom.

2. The polymer according to claim 1, wherein Q₁ in the formula (2) is represented by any one of the following formulas (2-1) to (2-4): 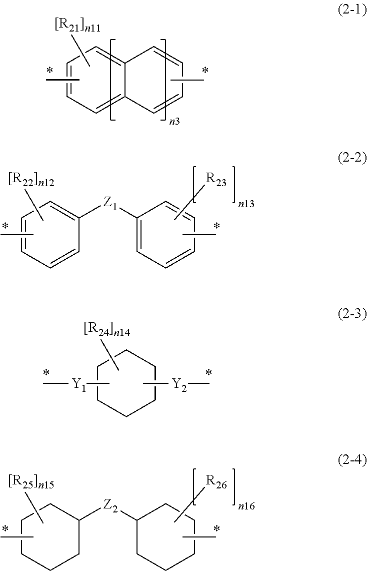
wherein in the formulas (2-1) to (2-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms; and * represents a bond;
in the formula (2-1), n3 represents 0 or 1; when n3 is 0, n11 represents an integer of 0 to 4; when n3 is 1, n11 represents an integer of 0 to 6; and when R₂₁ is 2 or more, 2 or more R₂₁ may be the same or different;
in the formula (2-2), Z₁ represents a single bond, an oxygen atom, a sulfur atom, a carbonyl group, a sulfonyl group, or an alkylene group having 1 to 6 carbon atoms; n12 and n13 each independently represent an integer of 0 to 4; when R₂₂ is 2 or more, 2 or more R₂₂ may be the same or different; and when R₂₃ is 2 or more, 2 or more R₂₃ may be the same or different;
in the formula (2-3), Y1 and Y2 each independently represent a single bond or an alkylene group having 1 to 6 carbon atoms; and n14 represents an integer of 0 to 4; when R₂₄ is 2 or more, 2 or more R₂₄ may be the same or different; and
in the formula (2-4), Z₂ represents a single bond, an oxygen atom, a sulfur atom, a carbonyl group, a sulfonyl group, or an alkylene group having 1 to 6 carbon atoms; n15 and n16 each independently represent an integer of 0 to 4; when R₂₅ is 2 or more, 2 or more R₂₅ may be the same or different; and when R₂₆ is 2 or more, 2 or more R₂₆ may be the same or different.

3. The polymer according to claim 1, wherein X₁ in the formula (1) is represented by the formula (1-3).

4. The polymer according to claim 1, wherein a molar ratio (M1:M2) between the partial structure (M1) represented by the formula (1) and the partial structure (M2) represented by the formula (2) is 95:5 to 40:60.

5. The polymer according to claim 1, wherein a molar ratio [(M1+M2):M3] of a sum of the partial structure (M1) represented by the formula (1) and the partial structure (M2) represented by the formula (2) to the partial structure represented by the formula (3) is 60:40 to 40:60.

6. The polymer according to claim 1, having a repeating unit represented by the following formula (A) and a repeating unit represented by the following formula (B): 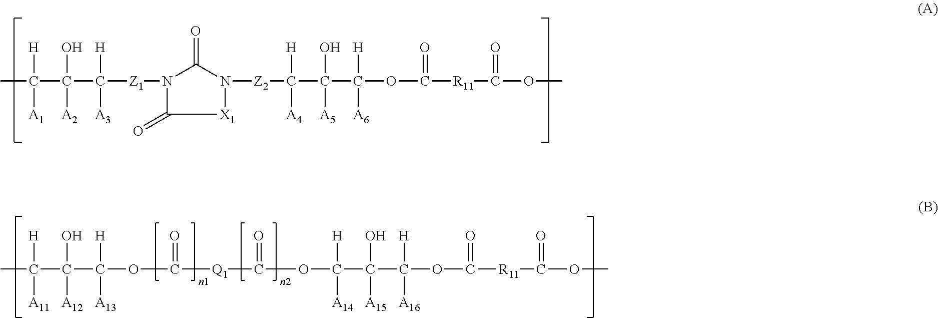
wherein in the formula (A), X₁, Z₁, Z₂, A₁, A₂, A₃, A₄, A₅, and A₆ are the same as X₁, Z₁, Z₂, A₁, A₂, A₃, A₄, As, and A₆ in the formula (1), respectively; and R₁₁ is the same as R₁₁ in the formula (3),
in the formula (B), Q₁, A₁₁, A₁₂, A₁₃, A₁₄, A₁₅, A₁₆, n1 and n2 are the same as Q₁, A₁₁, A₁₂, A₁₃, A₁₄, A₁₅, A₁₆, n1 and n2 in the formula (2), respectively; and R₁₁ is the same as R₁₁ in the formula (3).

7. The polymer according to claim 1, having a weight average molecular weight of 1,000 to 50,000.

8. A protective-film forming composition for forming a protective film for protecting an inorganic film formed on a surface of a semiconductor substrate from wet etching, the composition comprising:
the polymer according to claim 1 and a solvent.

9. The protective-film forming composition according to claim 8, the composition further comprising at least one of a crosslinking agent, an acid generator, a compound represented by the following formula (1a), and a compound represented by following formula (1b): 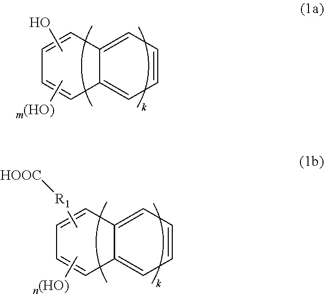
wherein in the formulae (1a) and (1b), R₁ represents a single bond, an alkylene group having 1 to 4 carbon atoms, or an alkenylene group having 2 to 4 carbon atoms having one or two carbon-carbon double bonds; k represents 0 or 1; m represents an integer of 1 to 3; and n represents an integer of 2 to 4.

10. A protective film for a wet etching solution for a semiconductor which is a baked product of an applied film formed of the protective-film forming composition according to claim 8.

11. A method for manufacturing a substrate with a protective film, the method comprising a step of forming a protective film by applying the protective-film forming composition according to claim 8 on a stepped semiconductor substrate and baking the composition.

12. A method for manufacturing a substrate with a resist pattern used for manufacturing a semiconductor, the method comprising:
a step of applying the protective-film forming composition according to claim 8 on a semiconductor substrate and baking the composition to form a protective film as a resist underlayer film; and
a step of forming a resist film on the protective film directly or via another layer, and then forming a resist pattern by exposure and development.

13. A method for manufacturing a semiconductor device, the method comprising the steps of: forming a protective film using the protective-film forming composition according to claim 8 on a semiconductor substrate having an inorganic film formed on a surface; forming a resist pattern on the protective film directly or via another layer; dry-etching the protective film using the resist pattern as a mask to expose a surface of the inorganic film; and wet-etching the inorganic film using a wet etching solution for a semiconductor using the protective film after the dry etching as a mask.
